(19) United States
(12) Patent Application Publication
(10) Pub. No.: US 2025/0014984 A1
(43) Pub. Date: Jan. 9, 2025

(54) CAPACITOR STRUCTURE INCLUDING WORK FUNCTION METAL LAYERS AND METHODS OF FORMATION

(71) Applicant: Taiwan Semiconductor Manufacturing Company, Ltd., Hsinchu (TW)

(72) Inventors: Bi-Shen LEE, Hsinchu (TW); Chia-Hua LIN, New Taipei City (TW); Hai-Dang TRINH, Hsinchu (TW); Chung-Yi YU, Hsin-Chu (TW); Cheng-Yuan TSAI, Chu-Pei City (TW)

(21) Appl. No.: 18/346,495

(22) Filed: Jul. 3, 2023

(51) Int. Cl. H01L 23/522; H01L 23/532

(52) U.S. Cl. CPC H01L 23/5223; H01L 23/53266; H01L 28/75; H01L 28/91

(57) ABSTRACT

In some implementations described herein, a capacitor structure may include a metal-insulator-metal structure in which work function metal layers are included between the insulator layer of the capacitor structure and the conductive electrode layers of the capacitor structure. The work function metal layers may enable high-k dielectric materials to be used for the insulator layer in that the work function metal layers may provide an increased electron barrier height between the insulator layer and the conductive electrode layers, which may increase the breakdown voltage and may reduce the current leakage for the capacitor structure.

### BACKGROUND

A semiconductor device may include one or more capacitor structures in a back end of line (BEOL) region of the semiconductor device. A capacitor structure may perform and/or support one or more functions in the semiconductor device, such as charge storage, analog to digital (A/D) conversion, circuit decoupling, and/or another function.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example environment in which systems and/or methods described herein may be implemented.

FIG. 2 is a diagram of a portion of an example semiconductor device described herein.

FIGS. 3A and 3B are diagrams of an example implementation of a capacitor structure described herein.

FIGS. 4A-4U are diagrams of an example implementation of forming a capacitor structure described herein.

FIGS. 5A, 5B, and 6 are diagrams of example implementations of a capacitor structure described herein.

FIGS. 7 and 8 are diagrams of example performance data related to a capacitor structure described herein.

FIG. 9 is a diagram of example components of a device described herein.

FIG. 10 is a flowchart of an example process associated with forming a capacitor structure including work function metal layers.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a capacitor structure includes a metal-insulator-metal (MIM) structure in which an insulator layer is sandwiched between two conductive electrode layers. The insulator layer may be formed on a first conductive electrode layer (e.g., a capacitor bottom metal (CBM) layer), and a second conductive electrode layer (e.g., a capacitor top metal (CTM) layer) may be formed on the insulator layer.

High dielectric constant (high-k) dielectric materials may offer desirable improvements in a capacitor structure for the insulator layer. Capacitive capacity of the capacitor structure may be directly proportional to the dielectric constant of the insulator layer. Therefore, increasing the dielectric constant of the insulator layer, such as by using a high-k dielectric material for the insulator layer, may provide increased capacitive capacity for the capacitor structure.

However, high-k dielectric materials may have drawbacks such as lower/smaller bandgaps relative to low dielectric constant (low-k) dielectric materials. Thus, while including a high-k dielectric material in an insulator layer of a capacitor structure may provide increased capacitive capacity for the capacitor structure, the high-k dielectric material may result in a lesser breakdown voltage and/or greater current leakage relative to the use of a low-k dielectric material for the insulator layer.

In some implementations described herein, a capacitor structure may include a metal-insulator-metal (MIM) structure in which work function metal layers are included between the insulator layer of the capacitor structure and the conductive electrode layers of the capacitor structure. The work function metal layers may enable high-k dielectric materials to be used for the insulator layer in that the work function metal layers may provide an increased electron barrier height between the insulator layer and the conductive electrode layers, which may increase the breakdown voltage and may reduce the current leakage for the capacitor structure.

In this way, the work function metal layers may increase the electron barrier height between the insulator layer and the conductive electrode layers, thereby enabling the capacitive capacity of the capacitor structure to be increased through the inclusion of high-k dielectric materials while minimizing the current leakage and/or breakdown voltage impact from the high-k dielectric materials.

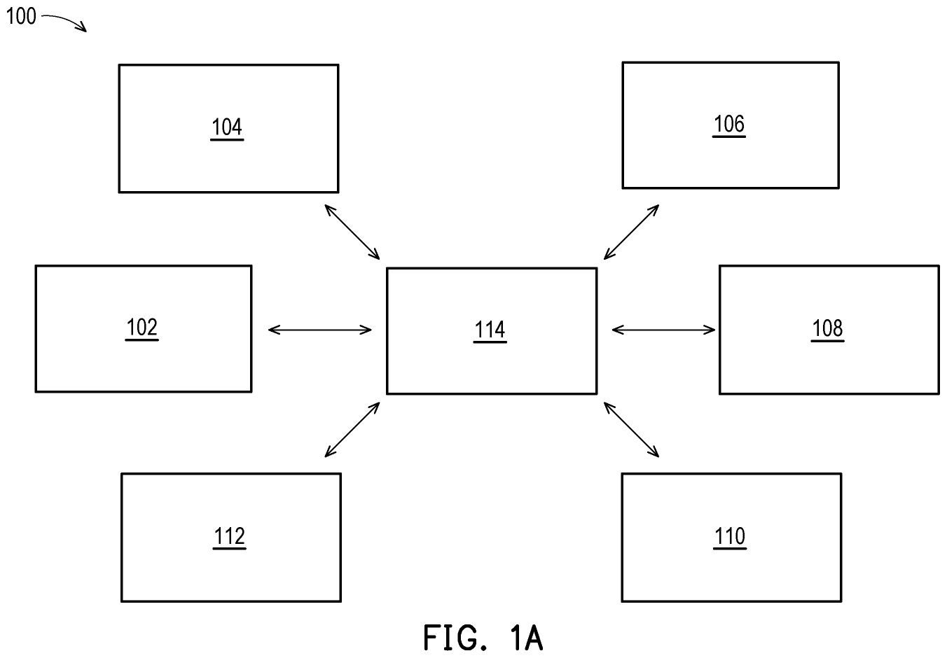

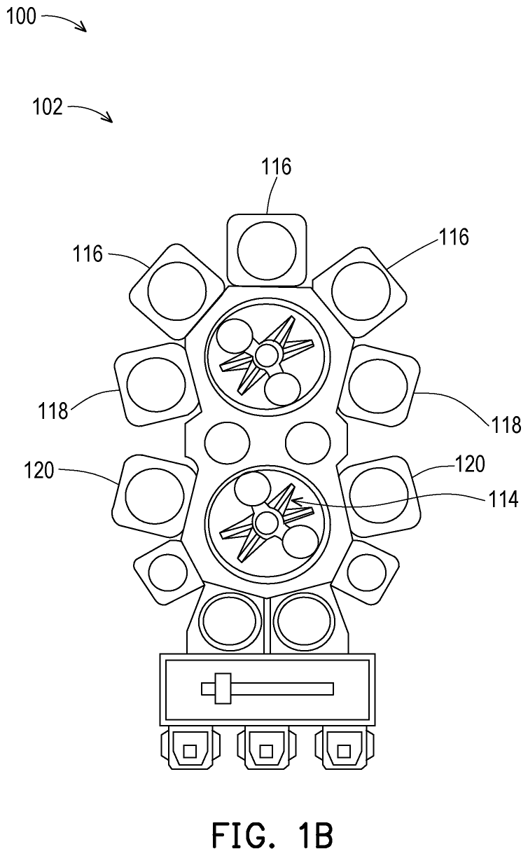

FIGS. 1A and 1B are diagrams of an example environment 100 in which systems and/or methods described herein may be implemented. As shown in FIG. 1A, the environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

FIG. 1B illustrated a diagram of an example implementation of a deposition tool 102. The deposition tool 102 may include a cluster tool that includes a plurality of processing chambers. Different subsets of the processing chambers of the deposition tool 102 may be configured to perform different types of semiconductor processing operations. For example, the deposition tool 102 may include one or more first processing chambers 116 configured to perform a deposition operation, such as a CVD operation, an ALD operation, a PVD operation, an epitaxy operation, a PECVD operation, an LPCVD operation, an HDP-CVD operation, an SACVD, a PEALD operation, and/or another type of deposition operation. In some implementations, two or more of the first processing chambers 116 may be configured to deposit different materials.

As another example, the deposition tool 102 may include one or more second processing chamber 118 configured to perform a surface treatment operation. For example, a second processing chamber 118 may be configured to perform a surface treatment operation on a layer of a semiconductor device using nitrous oxide (N₂O) and/or another surface treatment chemical. As another example, the deposition tool 102 may include one or more second processing chambers 118 configured to perform a degas operation in which processing gasses and/or byproduct gasses are removed from the deposition tool 102 (e.g., in preparation for transferring semiconductor devices into and/or out of the deposition tool 102).

The deposition tool 102 may further include one or more wafer/die transport tool 114 to transport semiconductor devices between the processing chambers of the deposition tool 102. In some implementations, the environment within the deposition tool 102 is sealed and environmentally controlled to prevent or reduce the likelihood of contamination of semiconductor devices processed in the deposition tool 102. A wafer/die transport tool 114 of the deposition tool 102 may be configured to transfer a semiconductor device between processing chambers of the deposition tool 102 without exposing the semiconductor devices to the external environment outside of the deposition tool 102. In this way, the wafer/die transport tool 114 may transfer a semiconductor device from a first processing chamber 116 to a second processing chamber 118 “in-situ” (e.g., without breaking the vacuum in which the semiconductor device is located), and/or may transfer a semiconductor device from a second processing chamber 118 to a first processing chamber 116 “in-situ” (e.g., without breaking the vacuum in which the semiconductor device is located), among other examples.

In some implementations, one or more of the semiconductor processing tools 102-112 and/or the wafer/die transport tool 114 may perform one or more semiconductor processing operations. The one or more semiconductor processing operations include, for example, forming a first conductive layer of a capacitor structure in a semiconductor device. The one or more semiconductor processing operations include forming, over the first conductive layer, a first work function metal layer. The one or more semiconductor processing operations include forming, over the first work function metal layer, an insulator layer of the capacitor structure. The one or more semiconductor processing operations include forming, over the insulator layer, a second work function metal layer. The one or more semiconductor processing operations include forming, over the second work function metal layer, a second conductive layer of the capacitor structure.

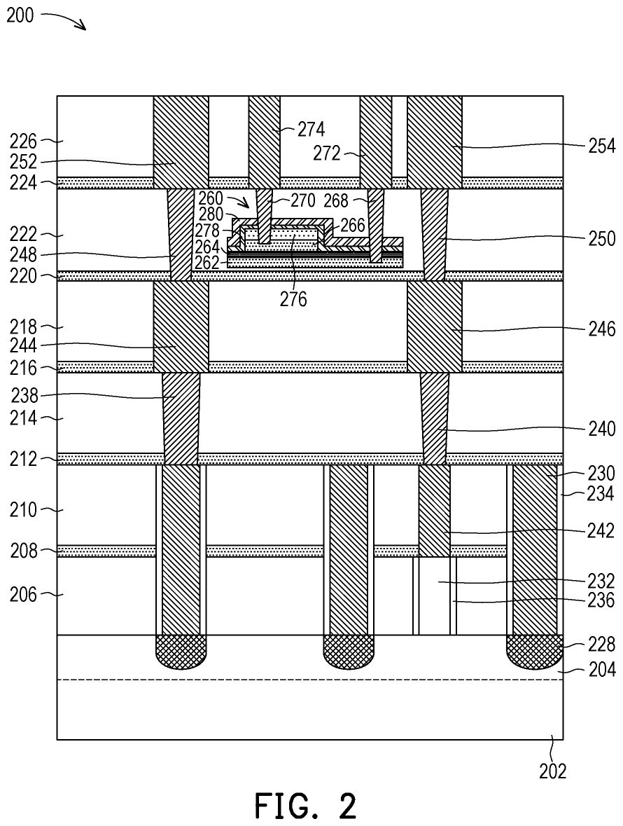

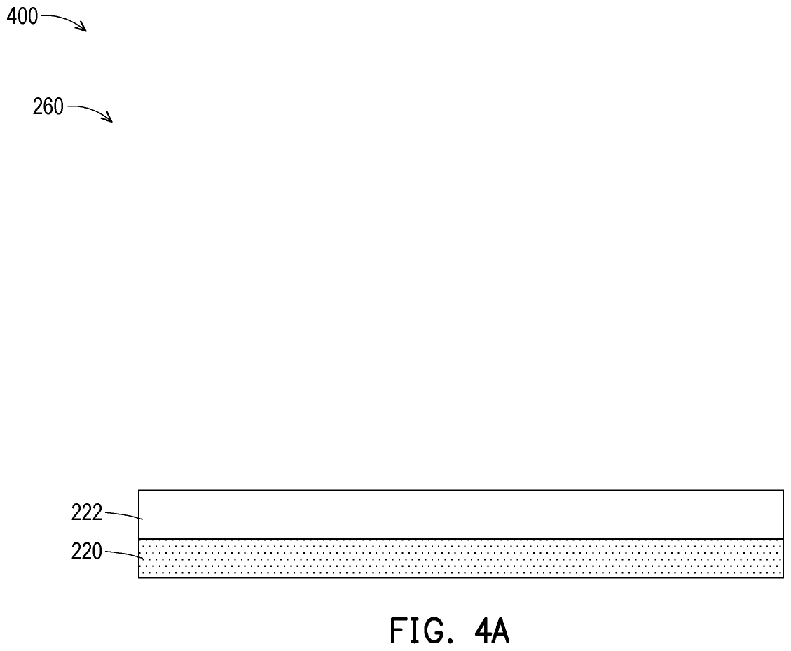

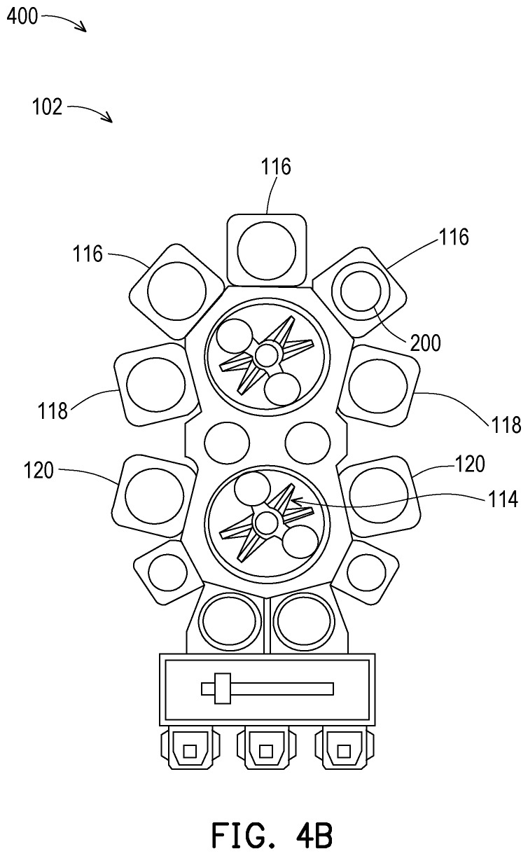

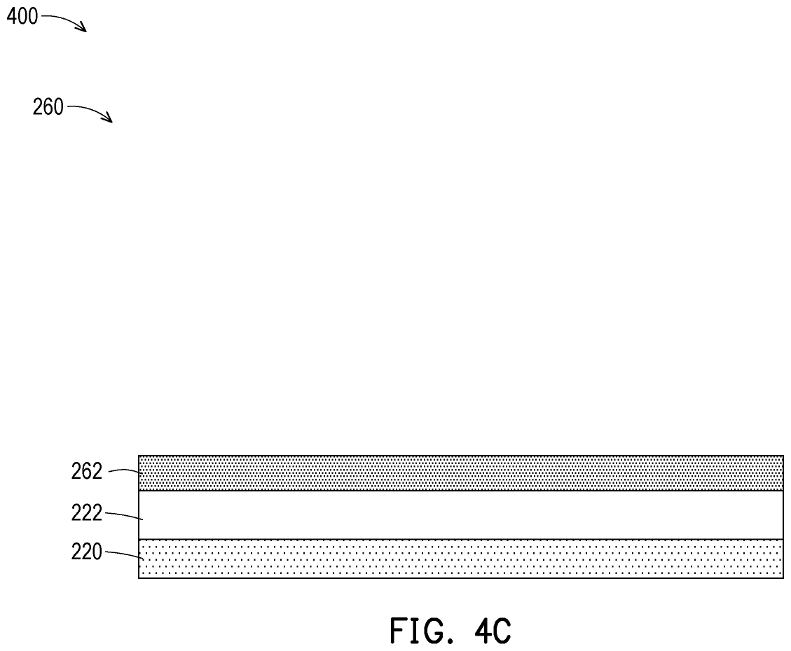

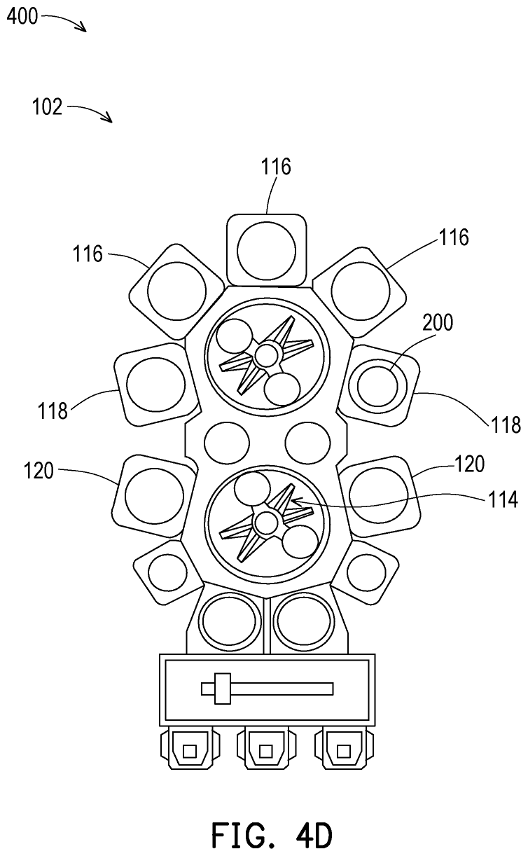

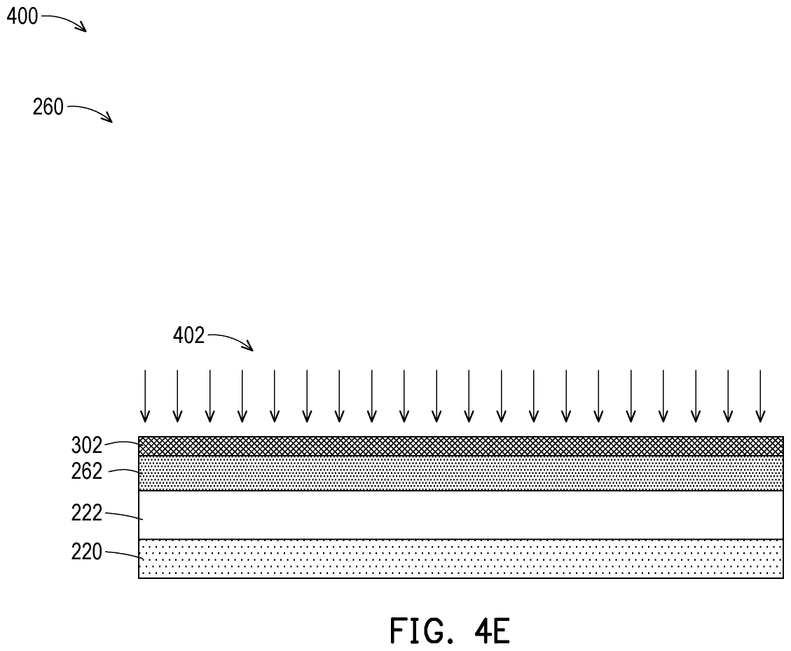

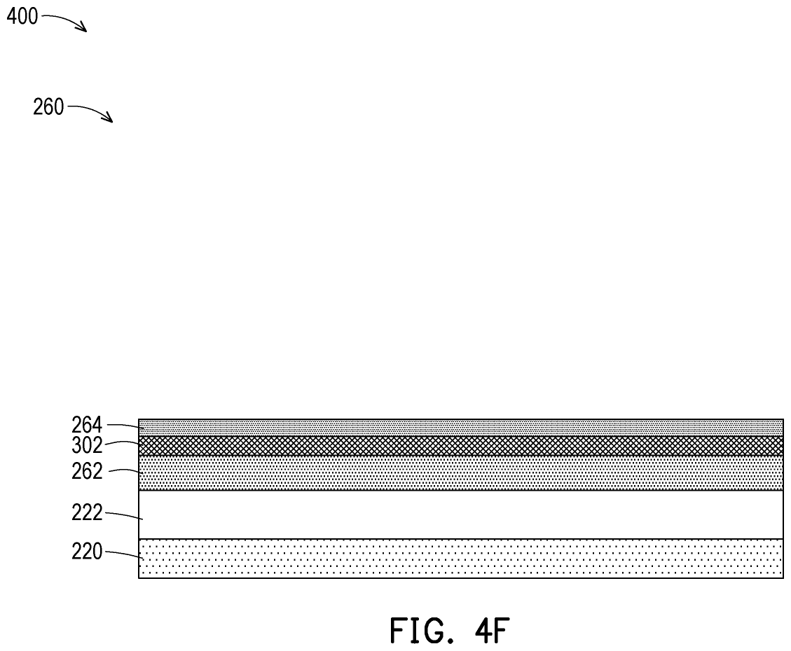

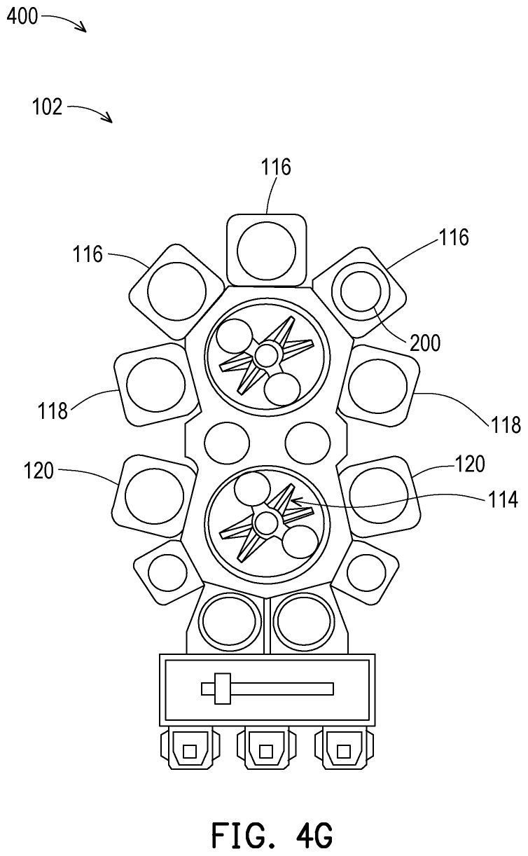

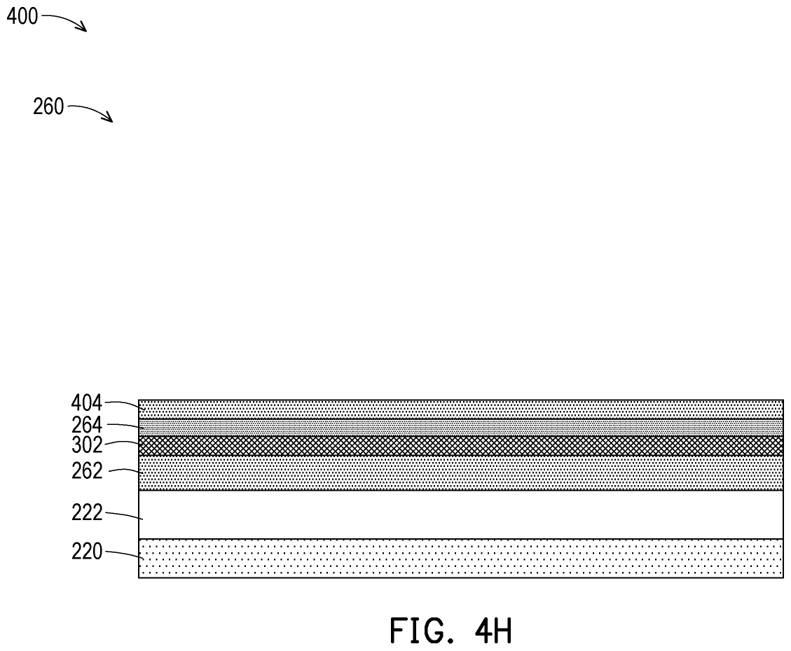

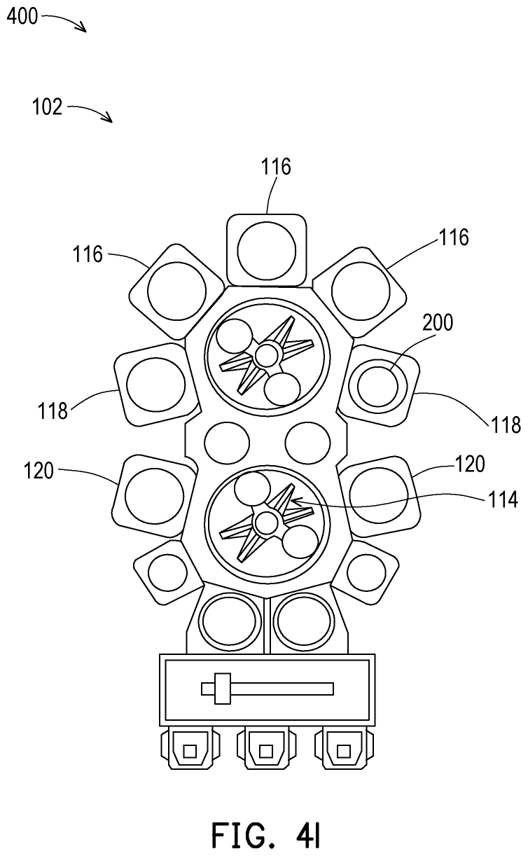

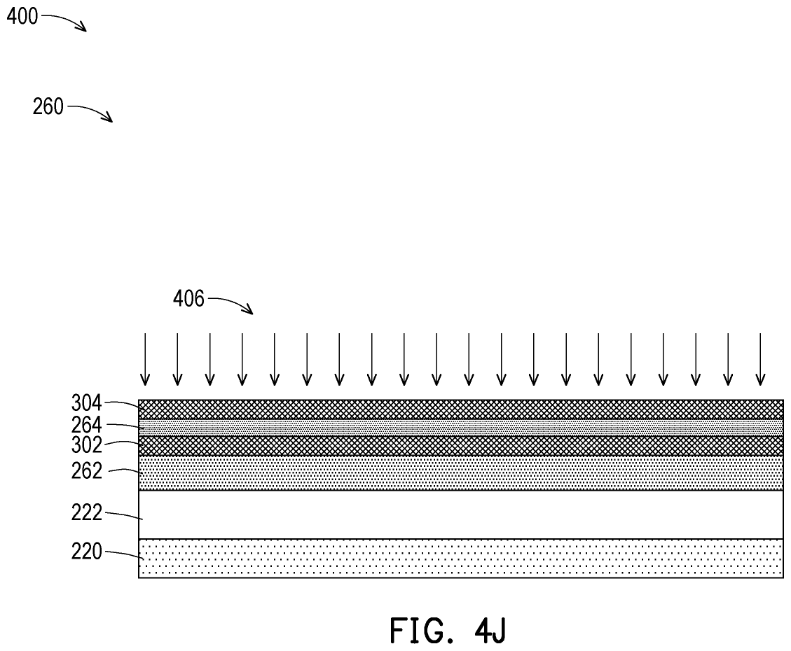

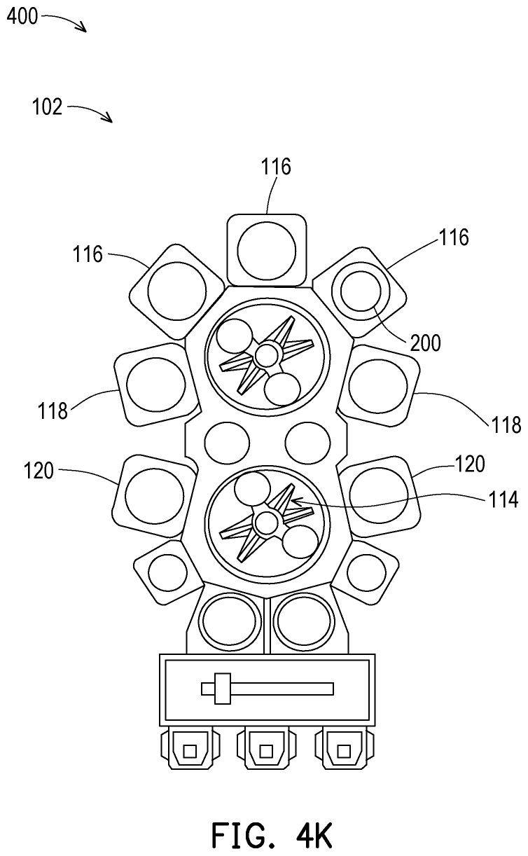

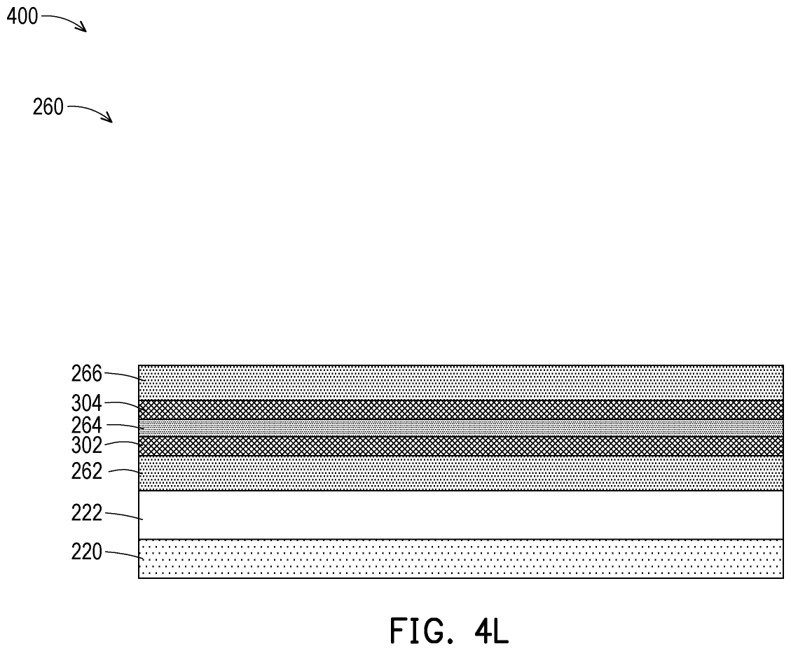

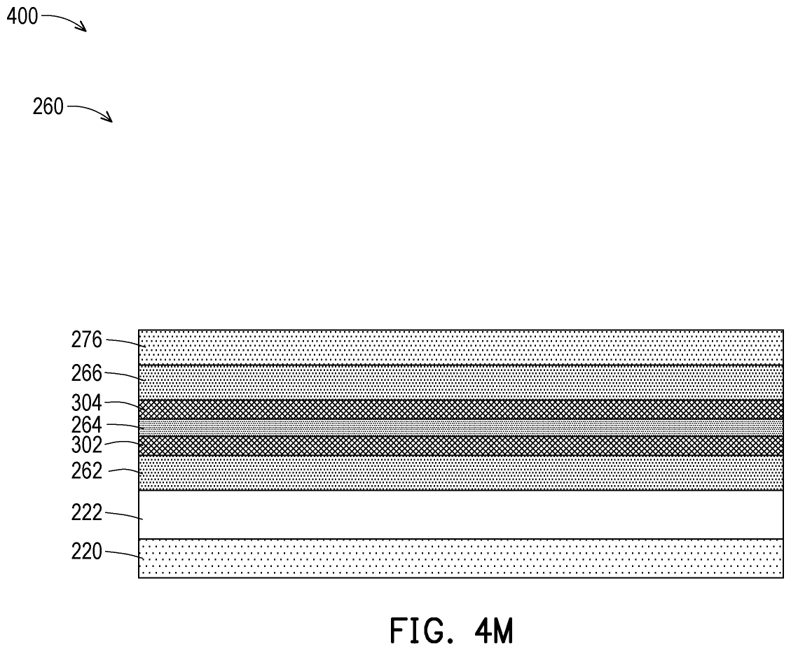

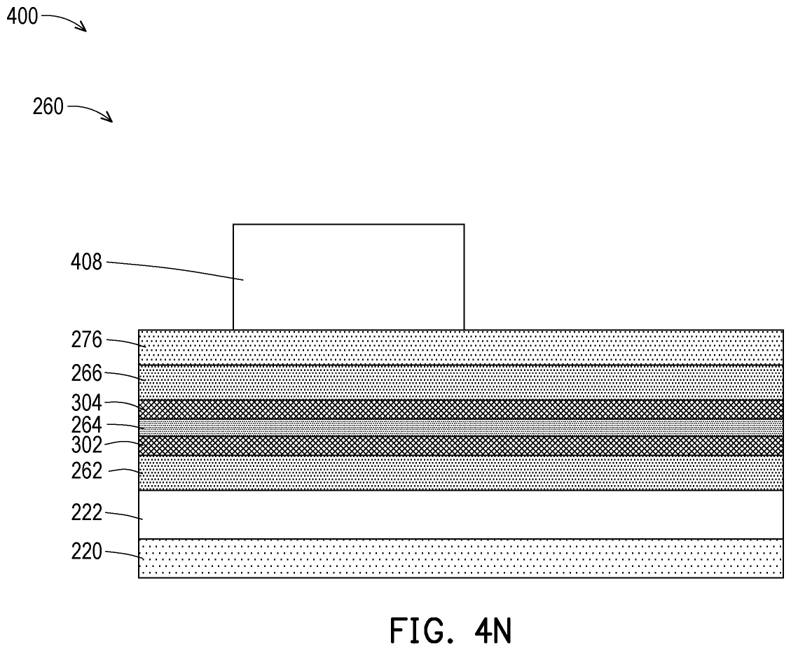

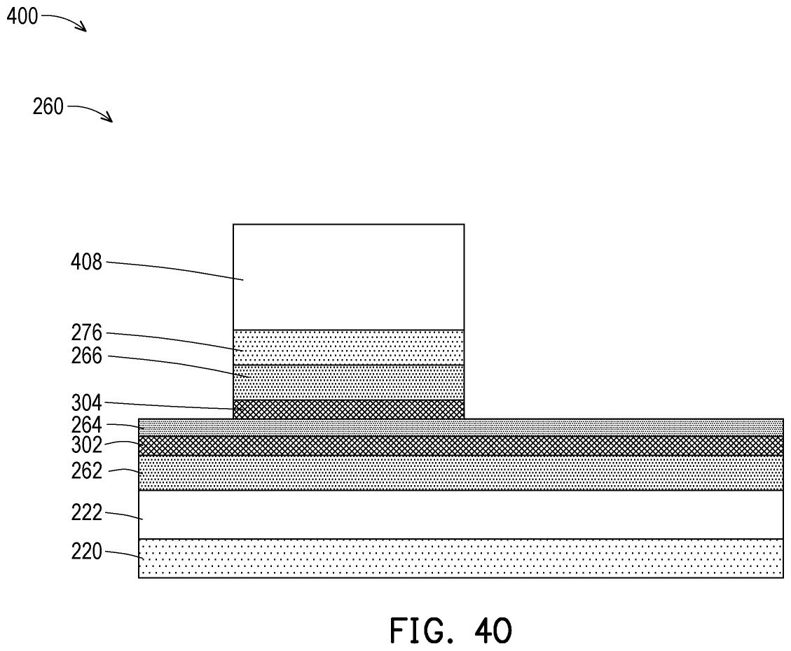

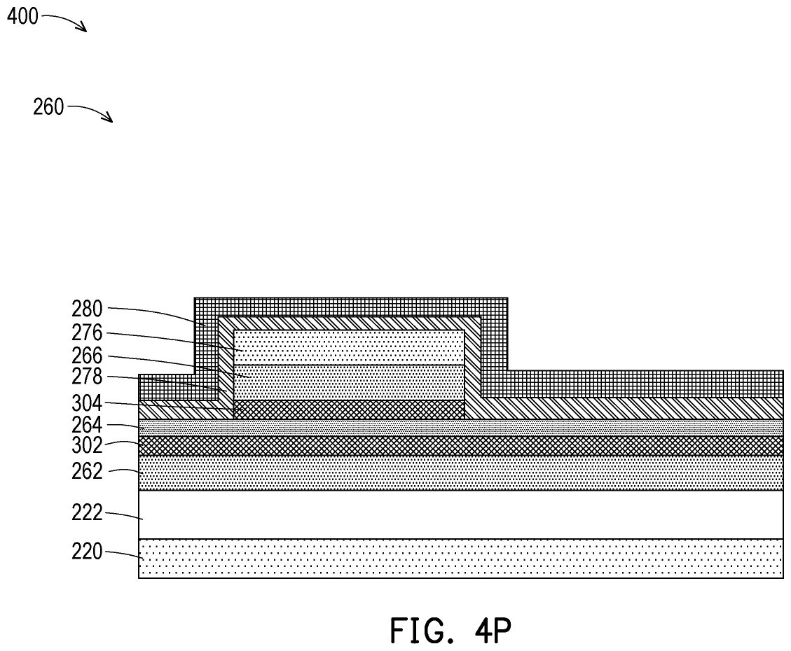

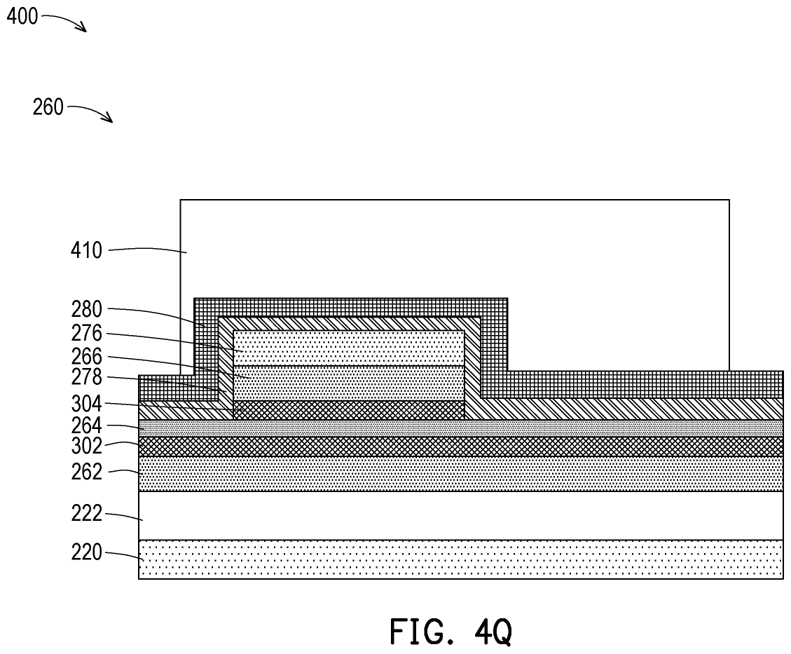

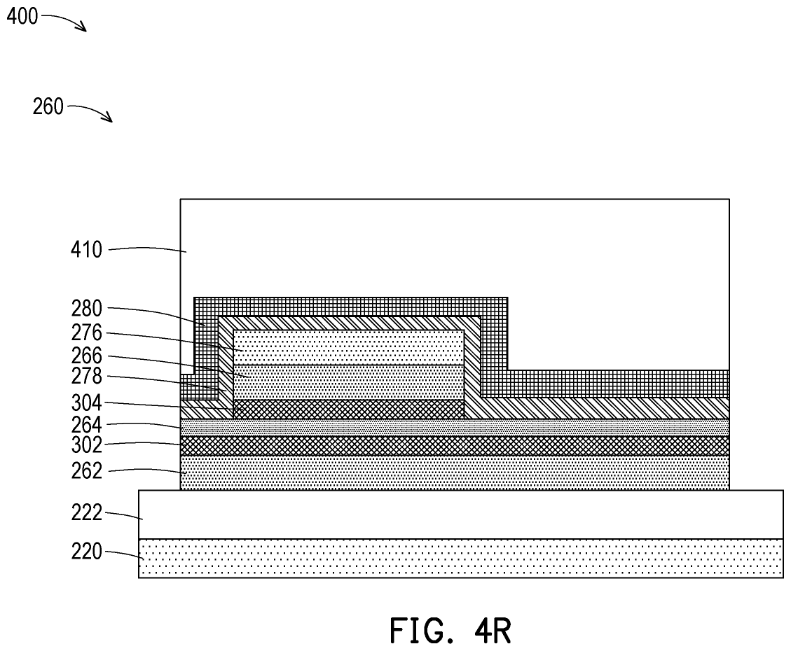

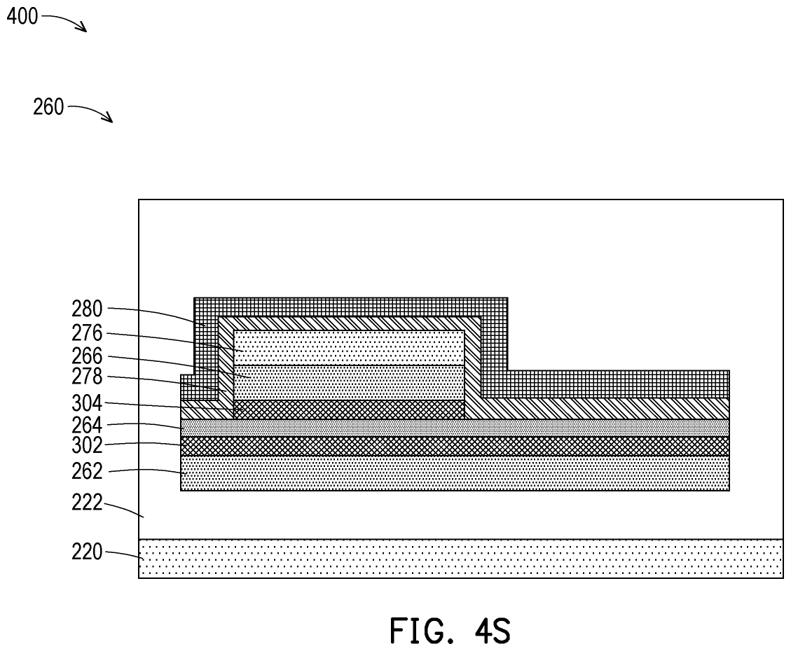

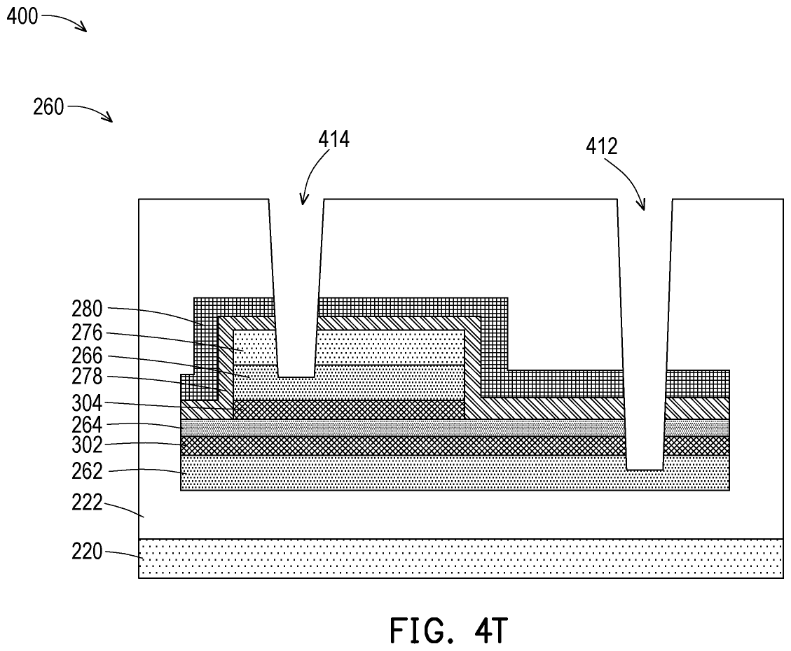

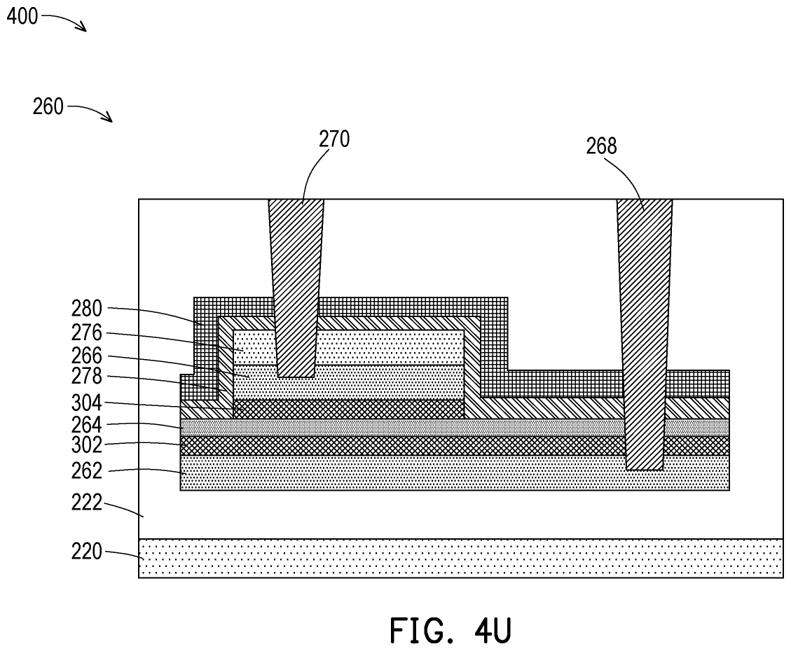

In some implementations, the one or more semiconductor processing operations described herein form device structures described in connection with FIGS. 2, 3A, 3B, 5A, 5B, and/or 6. Additionally, or alternatively, the one or more semiconductor processing operations may correspond to semiconductor processing operations described in connection with FIGS. 4A-4U.

The number and arrangement of devices shown in FIGS. 1A and 1B are provided as one or more examples. In practice, there may be additional devices, fewer devices, different devices, or differently arranged devices than those shown in FIGS. 1A and 1B. Furthermore, two or more devices shown in FIGS. 1A and 1B may be implemented within a single device, or a single device shown in FIGS. 1A and 1B may be implemented as multiple, distributed devices. Additionally, or alternatively, a set of devices (e.g., one or more devices) of the example environment 100 may perform one or more functions described as being performed by another set of devices of the example environment 100.

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM)), an image sensor device (e.g., a complementary metal oxide semiconductor (CMOS) image sensor (CIS) device), a semiconductor logic device, a processor, an input/output device, or another type of semiconductor device that includes one or more transistors.

The semiconductor device 200 includes a substrate 202. In some implementations, the semiconductor device 200 includes a fin structure 204 that extends above the substrate 202. The semiconductor device 200 includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source or drain regions of the transistors included in the semiconductor device 200.

The epitaxial regions 228 are electrically connected to metal source or drain contacts 230 of the transistors included in the semiconductor device 200. The metal source or drain contacts (MDs or CAs) 230 include cobalt (Co), ruthenium (Ru), and/or another conductive or metal material. The transistors further include gates 232 (MGs), which are formed of a polysilicon material, a metal (e.g., tungsten (W) or another metal), and/or another type of conductive material. The metal source or drain contacts 230 and the gates 232 are electrically isolated by one or more sidewall spacers, including spacers 234 in each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gates 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200.

The metal source or drain contacts 230 are electrically connected to source or drain interconnects 238 (e.g., source/drain vias or VDs). One or more of the gates 232 are electrically connected to gate interconnects 240 (e.g., gate vias or VGs). The interconnects 238 and 240 include a conductive material such as tungsten, cobalt, ruthenium, copper, and/or another type of conductive material. In some implementations, the gates 232 are electrically connected to the gate interconnects 240 by gate contacts 242 (CB or MP) to reduce contact resistance between the gates 232 and the gate interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of BEOL layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes vias 248 and 250. The V0 via layer is electrically connected to an M1 metallization that includes conductive structures 252 and 254. In some implementations, the BEOL layers of the semiconductor device 200 includes additional metallization layers and/or vias that connect the semiconductor device 200 to a package. The BEOL region of the semiconductor device 200 may refer to the region of the semiconductor device 200 above the ESL 208, including the structures/layers 210-226 and 238-254.

As further shown in FIG. 2, the semiconductor device 200 may include one or more devices and/or structures in the BEOL region of the semiconductor device 200. For example, the semiconductor device 200 may include one or more capacitor structures 260 in the BEOL region of the semiconductor device 200. The capacitor structure(s) 260 may be included in one or more of the dielectric layers 210, 214, 218, 222, and/or 226 in the BEOL region of the semiconductor device 200.

A capacitor structure 260 may include a first conductive layer 262, an insulator layer 264, and a second conductive layer 266. The first conductive layer 262 and the second conductive layer 266 may correspond to the conductive electrode layers of the capacitor structure 260. The first conductive layer 262 may be referred to as the capacitor bottom metal (CBM) layer of the capacitor structure 260, and the second conductive layer 266 may be referred to as the capacitor top metal (CTM) layer of the capacitor structure 260. The insulator layer 264 may be located between the first conductive layer 262 and the second conductive layer 266. The first conductive layer 262, the insulator layer 264, and the second conductive layer 266 may form a metal-insulator-metal (MIM) structure of the capacitor structure 260.

The first conductive layer 262 and the second conductive layer 266 may each include one or more electrically conductive materials, such as one or more metals, one or more metal alloys, and/or one or more of another type of electrically conductive materials. Examples include tungsten (W), cobalt (Co), ruthenium (Ru), titanium (Ti), aluminum (Al), copper (Cu) or gold (Au), titanium nitride (TiN), and/or tantalum nitride (TaN), among other examples. The insulator layer 264 may include one or more electrically insulating and/or dielectric materials. In some implementations, the insulator layer 264 includes one or more dielectric materials having a relatively high dielectric constant (high-k), such as a dielectric constant greater relative to the dielectric constant of silicon dioxide (SiO₂). Examples include zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), yttrium titanium oxide (YₓTiO_{y} such as Y₂TiO₅), hafnium oxide (HfOₓ such as HfO₂), and/or tantalum oxide (TaₓO_{y} such as Ta₂O₅), among other examples.

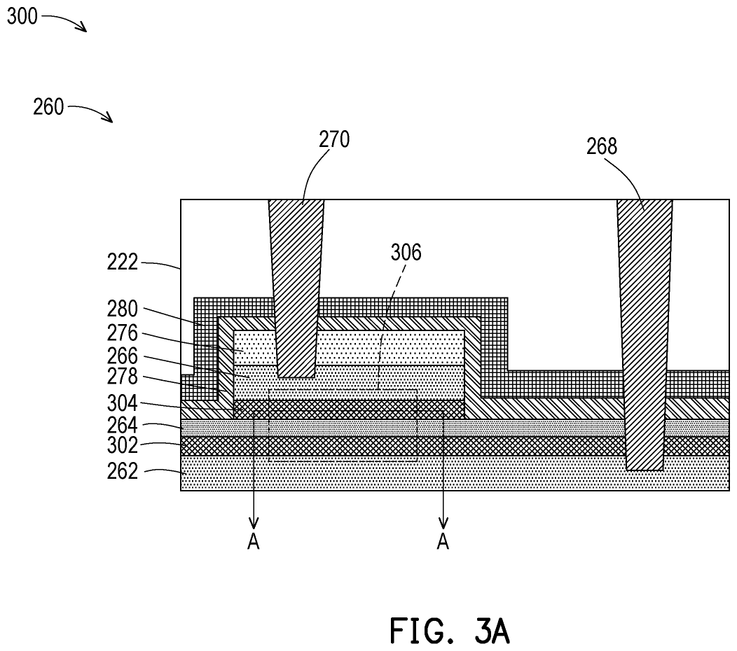

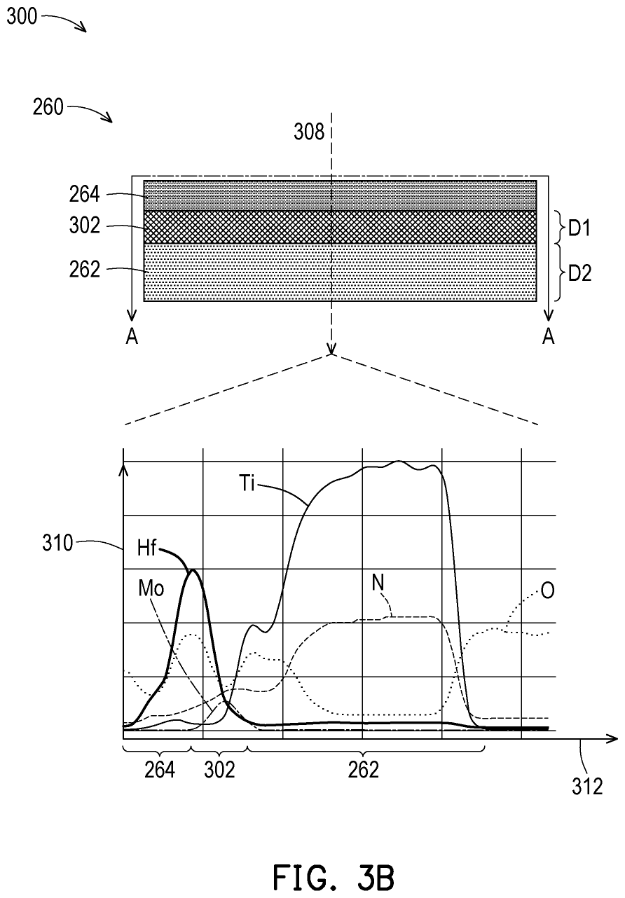

As described greater detail in in connection with FIGS. 3A, 3B, 4A-4U, 5A, 5B, 6, and elsewhere herein, the capacitor structure the 260 may include a work function metal layer between the insulator layer 264 of the capacitor structure 260 and the first conductive layer 262. Additionally, or alternatively, the capacitor structure 260 may include a work function metal layer between the insulator layer 264 of the capacitor structure 260 and the second conductive layer 266. Such work function metal layers may provide an increased electron barrier height between the insulator layer 264 and the first and second conductive layers 262 and 266, which may increase the breakdown voltage and may reduce the current leakage for the capacitor structure 260. In this way, the work function metal layers may enable the capacitive capacity of the capacitor structure 260 to be increased through the inclusion of high-k dielectric materials while minimizing the current leakage and/or breakdown voltage impact from the high-k dielectric materials.

As further shown in FIG. 2, the capacitor structure 260 may be electrically connected with contacts that electrically connect the capacitor structure 260 to other conductive structures in the semiconductor device 200. A bottom metal contact 268 may be located in the dielectric layer 222, and a top metal contact 270 may be located in the dielectric layer 222. The bottom metal contact 268 may be electrically connected with the first conductive layer 262. The top metal contact 270 may be electrically connected with the second conductive layer 266. The second conductive layer 266 may have a width that is less than the width of the first conductive layer 262 such that the bottom metal contact 268 can land on the first conductive layer 262 without contacting (and electrically shorting to) the second conductive layer 266. The bottom metal contact 268 and the top metal contact 270 may each include tungsten (W), cobalt (Co), ruthenium (Ru), titanium (Ti), aluminum (Al), copper (Cu), and/or gold (Au), among other examples of conductive materials.

The bottom metal contact 268 may be physically coupled and/or electrically coupled with a conductive structure 272 and/or another type of BEOL metallization layer. The top metal contact 270 may be physically coupled and/or electrically coupled with a conductive structure 274 and/or another type of BEOL metallization layer. The conductive structures 272 and 274 may each include tungsten (W), cobalt (Co), ruthenium (Ru), titanium (Ti), aluminum (Al), copper (Cu), and/or gold (Au), among other examples of conductive materials. The conductive structures 272 and 274 may be included in the dielectric layer 226 and may be extend through the ESL 224. In some implementations, the conductive structures 272 and 274 are top metal layers in the semiconductor device 200.

As further shown in FIG. 2, one or more capping layers, such as capping layer 276, a capping layer 278, and/or a capping layer 280, among other examples. The capping layers 276-280 may be included over and/or on the capacitor structure 260. The capping layers 276-280 may electrically isolate the capacitor structure 260 from other structures in the dielectric layer 226. Additionally, and/or alternatively, the capping layers 276-280 may function as a hard mask layer and/or an etch stop layer during manufacturing of the capacitor structure 260.

As indicated above, FIG. 2 is provided as an example. Other examples may differ from what is described with regard to FIG. 2.

FIGS. 3A and 3B are diagrams of an example implementation 300 of a capacitor structure 260 described herein. The capacitor structure 260 may be included in a semiconductor device, such as the semiconductor device 200 described herein. Furthermore, FIG. 3A shows a partial section A-A of the capacitor structure 260 that is used in connection with FIG. 3B to describe an elemental composition of a plurality of layers of the capacitor structure 260.

As shown in FIG. 3A, the capacitor structure 260 may include a first conductive layer 262, an insulator layer 264 over the first conductive layer 262, and a second conductive layer 266 over the insulator layer 264. The capacitor structure 260 may further include capping layers 276-280, and may be electrically connected and/or physically connected with a bottom metal contact 268 and a top metal contact 270.

As further shown in FIG. 3A, the capacitor structure 260 may include one or more work function metal layers to increase the capacitive capacity of the capacitor structure 260 through the inclusion of high-k dielectric materials while minimizing the current leakage and/or breakdown voltage impact from the high-k dielectric materials. For example, the capacitor structure 260 may include a first work function metal layer 302 between the first conductive layer 262 and the insulator layer 264. The first work function metal layer 302 may be included over and/or on the first conductive layer 262, and the insulator layer 264 may be included over and/or on the first work function metal layer 302. As another example, the capacitor structure 260 may include a second work function metal layer 304 between the second conductive layer 266 and the insulator layer 264. The second work function metal layer 304 may be included over and/or on the insulator layer 264, and the second conductive layer 266 may be included over and/or on the second work function metal layer 304.

In FIG. 3A, the first conductive layer 262, the first work function metal layer 302, the insulator layer 264, the second work function metal layer 304, and the second conductive layer 266 are approximately planar. Furthermore, and in FIG. 3A, the first work function metal layer 302, the insulator layer 264, the second work function metal layer 304, and the second conductive layer 266 may be used for a single capacitor plate structure 306 (and correspond to a single level structure).

In some implementations, the first conductive layer 262 includes a low resistivity bulk (LRB) material such as a titanium nitride material (TiN), a tantalum nitride material (TaN), a tungsten material (W), or a molybdenum material (Mo). Based on the material of the first conductive layer 262 and to increase the electron barrier height between the insulator layer 264 and the first conductive layer 262, the first work function metal layer 302 may include a high work function inert (HWFI) metal material. As examples, the HWFI metal material may include a gold material (Au), a silver material (Ag), a palladium material (Pd), a platinum material (Pt), an iridium material (Ir), a ruthenium material (Ru), a ruthenium oxide material (RuOx), a cobalt material (Co), a nickel material (Ni), a copper material (Cu), a tungsten carbon nitride material (WCN), a tungsten nitride material (WN), or a molybdenum nitride material (MoN).

A material of the first conductive layer 262 and/or the second conductive layer 266 may include a resistivity property that is less than approximately 150 micro-ohms·centimeter (μΩ·cm). If the material of the first conductive layer 262 and/or the second conductive layer 266 is greater than approximately 150 uΩ·cm, a capacitance of the capacitor structure 260 may increase and fail to satisfy a performance threshold. However, other values and/or ranges for the resistivity of the first conductive layer 262 and/or the second conductive layer 266 are within the scope of the present disclosure.

Additionally, or alternatively, material of the work function metal layers 302 and/or 304 may include a work function property such as a bandgap energy level that is included in a range of approximately 4.5 electron volts (eV) to approximately 6.0 eV. If the bandgap energy level is less than approximately 4.5 eV, a leakage characteristic of the capacitor structure 260 may increase and fail to satisfy a performance threshold. Additionally, or alternatively, and if the bandgap energy level is less than approximately 4.5 eV, a breakdown voltage (V_{BD}) of the capacitor structure 260 may decrease and fail to satisfy a performance threshold. Additionally, or alternatively, and if the bandgap energy level is greater than approximately 6.0 eV, a resistivity characteristic of the capacitor structure 260 may increase and fail to satisfy a performance threshold. However, other values and/or ranges for the bandgap energy level of the work function metal layers 302 and/or 304 are within the scope of the present disclosure.

Additionally, or alternatively, material of the work function metal layers 302 and/or 304 may include a thermodynamic property such as a Gibbs free energy that is included in a range of approximately −135 kilojoules per mol (KJ/mol) to approximately −970 KJ/mol. If the Gibbs free energy is lesser than approximately −135 KJ/mol, excessive oxidation may occur at an interface between the insulator layer 264 and the work function metal layers 302 and/or 304 that increases a resistivity of the capacitor structure 260 and causes the capacitor structure 260 to not satisfy a performance threshold. If the Gibbs free energy is greater than approximately −970 KJ/mol, the material of the work function metal layers 302 and/or 304 may not be compatible with semiconductor manufacturing processes. However, other values and ranges for the Gibbs free energy of the work function metal layers 302 and/or 304 are within the scope of the present disclosure.

FIG. 3B illustrates an elemental composition of a plurality of layers of the capacitor structure 260 along a depth profile 308 of the capacitor structure 260. The elemental composition is illustrated as an atomic percentage 310 of one or more elements in the one or more layers as a function of depth 312 in the capacitor structure 260. In particular, the atomic percentage 310 of the one or more elements is illustrated from a top surface of the insulator layer 264 to a bottom surface of the first conductive layer 262. The depth profile 308 corresponds to the section A-A of FIG. 3A.

As shown in the depth profile 308 in FIG. 3B, the insulator layer 264 may include oxygen (O) and hafnium (Hf). In particular, the insulator layer 264 may include a hafnium oxide (HfOₓ such as HfO₂). The atomic percentage 310 of oxygen (or oxygen concentration) may be lesser relative to the atomic percentage 310 of hafnium (or hafnium concentration) within the insulator layer 264.

As further shown in the depth profile 308 in FIG. 3B, the first work function metal layer 302 may include molybdenum (Mo) and nitrogen (N). In particular, the first work function metal layer 302 may include a molybdenum nitride material (MoN). The atomic percentage 310 of the nitrogen (or nitrogen concentration) may be greater relative to the atomic percentage 310 of the molybdenum along the depth 312 in work function metal layer 302. As further shown in FIG. 3B, the atomic percentage 310 of oxygen in the first work function metal layer 302 changes between a top surface of the first work function metal layer 302 and a bottom surface of the first work function metal layer 302 (e.g., the atomic percentage 310 of the oxygen decreases between the top surface of the first work function metal layer 302 and the bottom surface of the work function metal layer 302). Furthermore, and as shown in FIG. 3B, the atomic percentage 310 of nitrogen in the first work function metal layer 302 changes between a top surface of the first work function metal layer 302 and a bottom surface of the first work function metal layer 302 (e.g., the atomic percentage 310 of the nitrogen increases between the top surface of the first work function metal layer 302 and the bottom surface of the work function metal layer 302) . . .

In some implementations, a thickness D1 of the first work function metal layer 302 is included in a range of approximately 5 angstroms (Å) to approximately 250 Å. If the thickness D1 is less than approximately 5 Å, process capabilities of semiconductor processing tools (e.g., the semiconductor processing tools 102-112) manufacturing the capacitor structure 260 may result in an uneven coverage of the first work function metal layer 302 and cause gaps (e.g., voids, pitting) in the capacitor structure 260. If the thickness D1 is greater than approximately 250 Å, a cost of the first work function metal layer 302 may increase a cost of a device including the capacitor structure 260 (e.g., the semiconductor device 200).

As shown in the depth profile 308 in FIG. 3B, the first conductive layer 262 may include titanium (Ti) and nitrogen (N). In particular, the first conductive layer 262 includes a titanium nitride material (TiₓN). The atomic percentage 310 of titanium may be approximately uniform along the depth 312 through the first conductive layer 262. Additionally, or alternatively, the atomic percentage 310 of nitrogen may be approximately uniform along the depth 312 through the first conductive layer 262. Additionally, or alternatively, the atomic percentage 310 of titanium may be greater relative to the atomic percentage 310 of nitrogen through the first conductive layer 262.

As further shown in the depth profile 308 in FIG. 3B, the insulator layer 264 may include oxygen (O) and hafnium (Hf). In particular, the insulator layer 264 may include a hafnium oxide (HfOₓ such as HfO₂). Near a surface of the insulator layer 264, the atomic percentage 310 of oxygen may be greater relative to the atomic percentage of hafnium.

In some implementations, a thickness D2 of the first conductive layer 262 is included in a range of approximately 5 angstroms (Å) to approximately 500 Å. If the thickness D2 is less than approximately 5 Å, process capabilities of semiconductor processing tools (e.g., the semiconductor processing tools 102-112) manufacturing the capacitor structure 260 may result in an uneven coverage of the first conductive layer 262 and cause gaps (e.g., voids, pitting) in the capacitor structure 260. If the thickness D2 is greater than approximately 500 Å, a cost of the first conductive layer 262 may increase a cost of a device including the capacitor structure 260 (e.g., the semiconductor device 200).

As indicated above, FIGS. 3A and 3B are provided as an example. Other examples may differ from what is described with regard to FIGS. 3A and 3B.

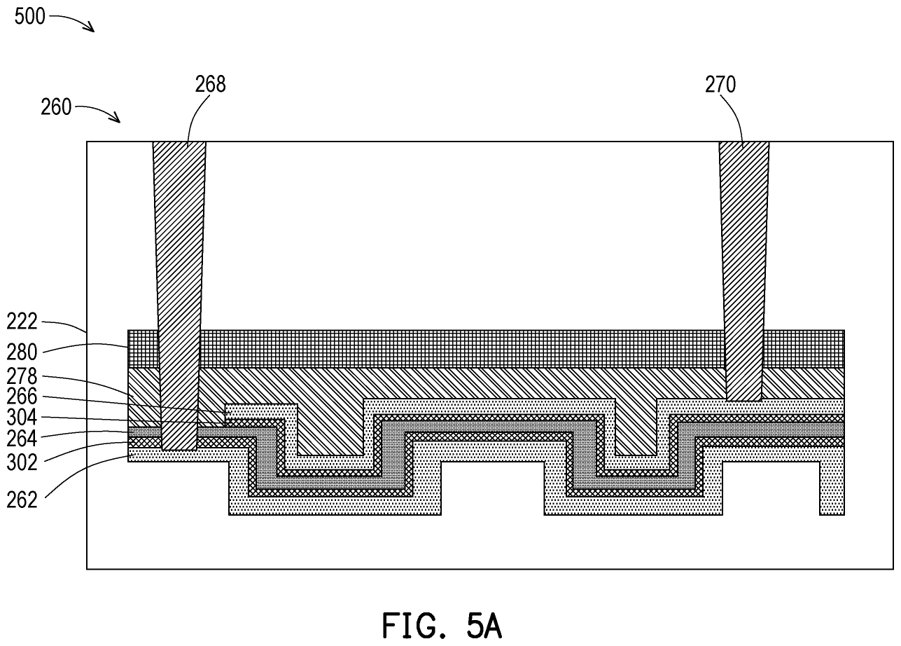

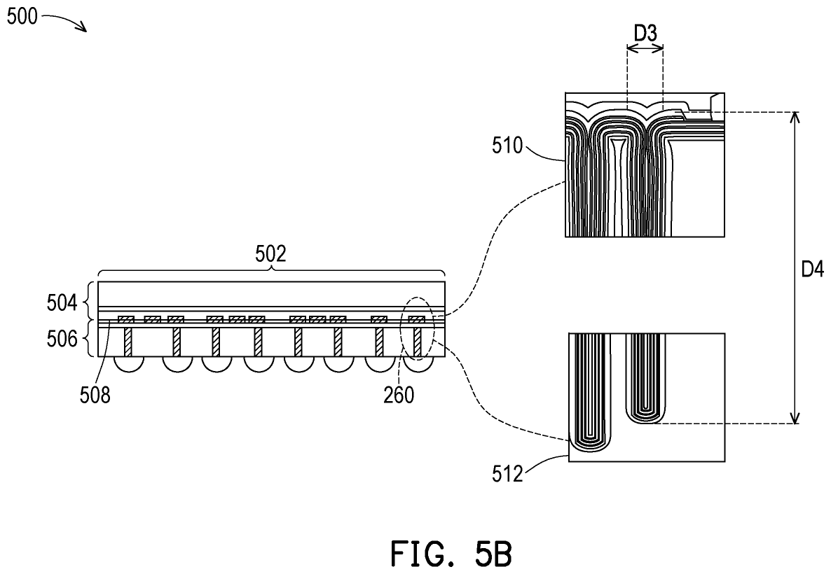

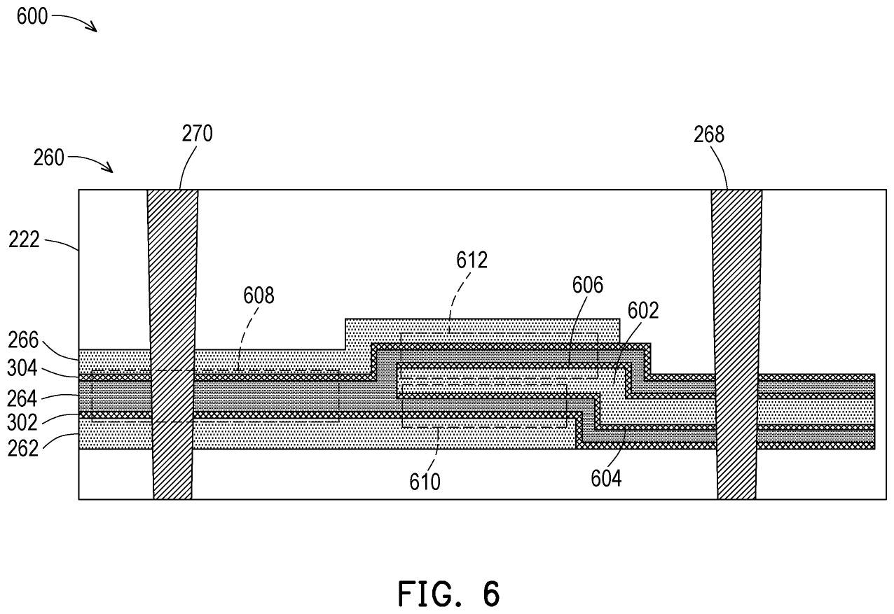

FIGS. 4A-4U are diagrams of an example implementation 400 of forming a capacitor structure 260 described herein. In particular, the example implementation 400 includes an example of forming a capacitor structure 260 that includes one or more work function metal layers, such as the work function metal layer 302 between the first conductive layer 262 and an insulator layer 264, and/or the second work function metal layer 304 between the second conductive layer 266 and the insulator layer 264. Furthermore, combinations of techniques and/or operations that are similar to those described in connection with FIGS. 4A-4U may be used to form various implementations the capacitor structure 260, including implementations described in connection with FIGS. 5A, 5B, and 6.

While FIGS. 4A-4U illustrate the process of forming the capacitor structure 260 to include both the first work function metal layer 302 and the second work function metal layer 304, other implementations include forming the capacitor structure 260 to include the first work function metal layer 302 and not the second work function metal layer 304, as well as forming the capacitor structure 260 to include the second work function metal layer 304 and not the first work function metal layer 302. In some implementations, the capacitor structure 260 may be formed in a semiconductor device, such as a semiconductor device 200. In some implementations, the capacitor structure 260 may be formed in a BEOL region of the semiconductor device 200.

Turning to FIG. 4A, one or more of the operations performed in connection with forming the capacitor structure 260 may be performed after one or more operations to form other layers and/or structures in the semiconductor device 200. For example, one or more of the operations performed in connection with forming the capacitor structure 260 may be performed after one or more operations to form an ESL 220 in the BEOL region of the semiconductor device 200, one or more operations to form a portion of a dielectric layer in the BEOL region of the semiconductor device 200, and/or one or more other operations.

As shown in FIG. 4B, the semiconductor device 200 may be positioned in a first processing chamber 116 of a deposition tool 102 in preparation for one or more deposition operations. The wafer/die transport tool 114 of the deposition tool 102 may transfer the semiconductor device 200 to the first processing chamber 116 from another processing chamber (e.g., a third processing chamber 120) and/or from a FOUP or another type of wafer carrier.

As shown in FIG. 4C, the first conductive layer 262 may be formed over and/or on the portion of the dielectric layer 222. The deposition tool 102 may deposit the first conductive layer 262 in a CVD operation, a PVD operation, an ALD operation, another deposition operation described above in connection with FIG. 1, and/or another suitable deposition operation. The deposition tool 102 may perform the deposition operation in the first processing chamber 116. In some implementations, the planarization tool 110 planarizes the first conductive layer 262 after the deposition tool 102 deposits the first conductive layer 262.

As shown in FIG. 4D, the semiconductor device 200 may be transferred from the first processing chamber 116 to a second processing chamber 118. In some implementations, the wafer/die transport tool 114 may transfer the semiconductor device 200 from the first processing chamber 116 to the second processing chamber 118 “in-situ” (e.g., without breaking a vacuum in which the semiconductor device 200 is located). This may reduce the likelihood of exposure of the semiconductor device 200 to humidity and/or another type of contaminant.

As shown in FIG. 4E, a surface treatment operation may be performed on the first conductive layer 262 using a surface treatment chemical 402. The surface treatment chemical 402 may include nitrous oxide (N₂O) and/or another type of surface treatment chemical 402 that reacts with the material of the first conductive layer 262. The deposition tool 102 may perform the surface treatment operation using the surface treatment chemical 402 in the second processing chamber 118.

The deposition tool 102 may perform the surface treatment operation to form the first work function metal layer 302 in and/or on the first conductive layer 262. In particular, the nitrous oxide (N₂O) of the surface treatment chemical 402 may react with the titanium nitride (e.g., TiₓN such as Ti₂N) in the first conductive layer 262 to form the titanium oxide (e.g., TiOₓ such as TiO₂) in the first work function metal layer 302 and the titanium nitride (TiN) in the first work function metal layer 302. The reaction between the material of the first conductive layer 262 and the nitrous oxide (N₂O) of the surface treatment chemical 402 may include:

Ti₂N+N₂O→TiN+TiO₂

where the titanium nitride (e.g., TiₓN such as Ti₂N) in the first conductive layer 262 reacts with the nitrous oxide (N₂O) of the surface treatment chemical 402 to form the titanium oxide (e.g., TiOₓ such as TiO₂) in the first work function metal layer 302 and the titanium nitride (TiN) in the first work function metal layer 302.

As shown in FIG. 4F, the insulator layer 264 is formed over and/or on the first work function metal layer 302. The deposition tool 102 may deposit the insulator layer 264 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the insulator layer 264 after the deposition tool 102 deposits the insulator layer 264.

As shown in FIG. 4G, the semiconductor device 200 may be positioned in a first processing chamber 116 of a deposition tool 102 in preparation for one or more deposition operations. The wafer/die transport tool 114 of the deposition tool 102 may transfer the semiconductor device 200 to the first processing chamber 116 from another processing chamber (e.g., a second processing chamber 118, a third processing chamber 120).

As shown in FIG. 4H, a base layer 404 may be formed over and/or on the insulator layer 264. The base layer 404 may include the same material that is to be included in the second conductive layer 266 that is to be subsequently formed for the capacitor structure 260. For example, the base layer 404 may include a nitrogen-containing material or a nitride-containing material such as a titanium nitride (TiₓN such as Ti₂N). The deposition tool 102 may deposit the base layer 404 in a CVD operation, a PVD operation, an ALD operation, another deposition operation described above in connection with FIG. 1, and/or another suitable deposition operation. The deposition tool 102 may perform the deposition operation in the first processing chamber 116. In some implementations, the planarization tool 110 planarizes the base layer 404 after the deposition tool 102 deposits the base layer 404.

As shown in FIG. 4I, the semiconductor device 200 may be transferred from the first processing chamber 116 to a second processing chamber 118 after the base layer 404 is formed. In some implementations, the wafer/die transport tool 114 may transfer the semiconductor device 200 from the first processing chamber 116 to the second processing chamber 118 “in-situ” (e.g., without breaking a vacuum in which the semiconductor device 200 is located). This may reduce the likelihood of exposure of the semiconductor device 200 to humidity and/or another type of contaminant.

As shown in FIG. 4J, a surface treatment operation may be performed on the base layer 404 using a surface treatment chemical 406. The surface treatment chemical 406 may include nitrous oxide (N₂O) and/or another type of surface treatment chemical 406 that reacts with the material of the base layer 404. The deposition tool 102 may perform the surface treatment operation using the surface treatment chemical 406 in the second processing chamber 118.

The deposition tool 102 may perform the surface treatment operation to form the second work function metal layer 304 in the base layer 404 and/or on the insulator layer 264. In particular, the nitrous oxide (N₂O) of the surface treatment chemical 406 may react with the titanium nitride (e.g., TiₓN such as Ti₂N) in the base layer 404 to form the titanium oxide (e.g., TiOₓ such as TiO₂) in the second work function metal layer 304 and the titanium nitride (TiN) in the second work function metal layer 304. The reaction between the material of the base layer 404 and the nitrous oxide (N₂O) of the surface treatment chemical 406 may include:

Ti₂N+N₂O→TiN+TiO₂

where the titanium nitride (e.g., TiₓN such as Ti₂N) in the base layer 404 reacts with the nitrous oxide (N₂O) of the surface treatment chemical 406 to form the titanium oxide (e.g., TiOₓ such as TiO₂) in the second work function metal layer 304 and the titanium nitride (TiN) in the second work function metal layer 304.

As shown in FIG. 4K, the semiconductor device 200 may be transferred from the second processing chamber 118 to a first processing chamber 116 after the second work function metal layer 304 is formed. In some implementations, the wafer/die transport tool 114 may transfer the semiconductor device 200 from the second processing chamber 118 to the first processing chamber 116 “in-situ” (e.g., without breaking a vacuum in which the semiconductor device 200 is located). This may reduce the likelihood of exposure of the semiconductor device 200 to humidity and/or another type of contaminant.

As shown in FIG. 4L, the second conductive layer 266 may be formed over and/or on the second work function metal layer 304. The deposition tool 102 may deposit the second conductive layer 266 in a CVD operation, a PVD operation, an ALD operation, another deposition operation described above in connection with FIG. 1, and/or another suitable deposition operation. The deposition tool 102 may perform the deposition operation in the first processing chamber 116. In some implementations, the planarization tool 110 planarizes the second conductive layer 266 after the deposition tool 102 deposits the second conductive layer 266.

As shown in FIG. 4M, the capping layer 276 is formed over and/or on the second conductive layer 266. The deposition tool 102 may deposit the capping layer 276 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the capping layer 276 after the deposition tool 102 deposits the capping layer 276.

As shown in FIG. 4N, a photoresist layer 408 is formed over and/or on a portion of the capping layer 276. A pattern in a photoresist layer 408 may be used to etch the capping layer 276, the second conductive layer 266, and the second work function metal layer 304 such that a bottom metal contact (e.g., the bottom metal contact) 268 may be formed to the first conductive layer 262. The deposition tool 102 may form the photoresist layer 408 on the capping layer 276. The exposure tool 104 may expose the photoresist layer 408 to a radiation source to pattern the photoresist layer 408. The developer tool 106 develops and removes portions of the photoresist layer 408 to expose the pattern.

As shown in FIG. 4O, the etch tool 108 etches the capping layer 276, the second conductive layer 266, and the second work function metal layer 304 based on the pattern in the photoresist layer 408. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, the etch tool 108 etches the capping layer 276 based on the pattern in the photoresist layer 408 to transfer the pattern the capping layer 276, and the etch tool 108 uses the pattern in the capping layer 276 as a hard mask to etch the second conductive layer 266 and/or the second work function metal layer 304. In some implementations, a photoresist removal tool removes the remaining portions of the photoresist layer 408 (e.g., using a chemical stripper, plasma ashing, and/or another technique).

As shown in FIG. 4P, the capping layer 278 and the capping layer 280 may be formed over and/or on the exposed portions of the insulator layer 264, over and/or on the top surface of the capping layer 276, and/or on the sidewalls of the second work function metal layer 304, the second conductive layer 266, and/or the capping layer 276. The capping layers 278 and 280 may electrically isolate the capacitor structure 260 from other layers and/or structures in the semiconductor device 200. The deposition tool 102 may conformally deposit the capping layer 278 and the capping layer 280 in a PVD operation, an ALD operation, a CVD operation, an epitaxy operation, an oxidation operation, another type of deposition operation described in connection with FIG. 1, and/or another suitable deposition operation.

As shown in FIG. 4Q, a photoresist layer 410 is formed over and/or on a portion of the capping layer 280. A pattern in the photoresist layer 410 may be used to etch the capping layer 280, the capping layer 278, the insulator layer 264, the first work function metal layer 302, and the first conductive layer 262 to define portions of a capacitor structure (e.g., the capacitor structure 260). The deposition tool 102 may form the photoresist layer 410 on the capping layer 280. The exposure tool 104 may expose the photoresist layer 410 to a radiation source to pattern the photoresist layer 410. The developer tool 106 develops and removes portions of the photoresist layer 410 to expose the pattern.

As shown in FIG. 4R, the etch tool 108 etches the capping layer 280, the capping layer 278, the insulator layer 264, the first work function metal layer 302, and the first conductive layer 262 based on the pattern in the photoresist layer 410 to define the first conductive layer 262. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a photoresist removal tool removes the remaining portions of the photoresist layer 410 (e.g., using a chemical stripper, plasma ashing, and/or another technique).

As shown in FIG. 4S, an additional portion of the dielectric layer 222 may be formed such that the dielectric layer 222 encapsulates the capacitor structure 260. The deposition tool 102 may deposit the additional portion of the dielectric layer 222 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the dielectric layer 222 after the deposition tool 102 deposits the additional portion of the dielectric layer 222.

As shown in FIG. 4T, a recess 412 is formed through the dielectric layer 222, through the capping layer 280, through the capping layer 278, through the insulator layer 264, through the first work function metal layer 302, and to the first conductive layer 262. The first conductive layer 262 is exposed through the recess 412.

In some implementations, a pattern in a photoresist layer is used to etch the dielectric layer 222, the capping layer 280, the capping layer 278, the insulator layer 264, and the first work function metal layer 302 to form the recess 412. In these implementations, the deposition tool 102 forms the photoresist layer over and/or on the dielectric layer 222. The exposure tool 104 exposes the photoresist layer to a radiation source to pattern the photoresist layer. The developer tool 106 develops and removes portions of the photoresist layer to expose the pattern. The etch tool 108 etches through the dielectric layer 222, through the capping layer 280, through the capping layer 278, through the insulator layer 264, through the first work function metal layer 302 based on the pattern to form the recess 412. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the recess 412 based on a pattern. In some implementations, a photoresist removal tool removes the remaining portions of the photoresist layer (e.g., using a chemical stripper, plasma ashing, and/or another technique).

As further shown in FIG. 4T, a recess 414 is formed through the dielectric layer 222, through the capping layer 280, through the capping layer 278, through the capping layer 276, and to the second conductive layer 266. The second conductive layer 266 is exposed through the recess 414.

In some implementations, a pattern in a photoresist layer is used to etch the dielectric layer 222, the capping layer 280, the capping layer 278, and the capping layer 276 to form the recess 414. In these implementations, the deposition tool 102 forms the photoresist layer over and/or on the dielectric layer 222. The exposure tool 104 exposes the photoresist layer to a radiation source to pattern the photoresist layer. The developer tool 106 develops and removes portions of the photoresist layer to expose the pattern. The etch tool 108 etches through the dielectric layer 222, through the capping layer 280, through the capping layer 278, and through the capping layer 276 based on the pattern to form the recess 414. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the recess 414 based on a pattern. In some implementations, a photoresist removal tool removes the remaining portions of the photoresist layer (e.g., using a chemical stripper, plasma ashing, and/or another technique).

As shown in FIG. 4U, a bottom metal contact 268 is formed in the recess 412. The bottom metal contact 268 is formed on the first conductive layer 262 (e.g., such that the bottom metal contact 268 lands on the first conductive layer 262 in the recess 412). The deposition tool 102 and/or the plating tool 112 may deposit the bottom metal contact 268 in a CVD operation, a PVD operation, an ALD operation, an electroplating operation, another deposition operation described above in connection with FIG. 1, and/or another suitable deposition operation. In some implementations, a seed layer is first deposited, and the bottom metal contact 268 is deposited on the seed layer. In some implementations, the planarization tool 110 planarizes the bottom metal contact 268 after the deposition tool 102 and/or the plating tool 112 deposits the bottom metal contact 268.

As further shown in FIG. 4U, a top metal contact 270 is formed in the recess 414. The top metal contact 270 is formed on the second conductive layer 266 (e.g., such that the top metal contact 270 lands on the second conductive layer 266 in the recess 414). The deposition tool 102 and/or the plating tool 112 may deposit the top metal contact 270 in a CVD operation, a PVD operation, an ALD operation, an electroplating operation, another deposition operation described above in connection with FIG. 1, and/or another suitable deposition operation. In some implementations, a seed layer is first deposited, and the top metal contact 270 is deposited on the seed layer. In some implementations, the planarization tool 110 planarizes the top metal contact 270 after the deposition tool 102 and/or the plating tool 112 deposits the top metal contact 270.

As indicated above, FIGS. 4A-4U are provided as an example. Other examples may differ from what is described with regard to FIGS. 4A-4U.

FIGS. 5A and 5B are diagrams of an example implementation 500 of a capacitor structure 260 described herein. In implementation 500, and in contrast to the approximately planar capacitor structure implementation 300 of FIGS. 3A and 3B, the capacitor structure 260 may correspond to a deep trench capacitor (DTC) structure (e.g., a non-planar capacitor structure). Additionally, one or more features of the capacitor structure 260 of the implementation 500 may be formed using one or more operations described in connection with FIGS. 4A-4U.

As shown in FIG. 5A, the dielectric layer 222 includes the capacitor structure 260. As further shown in FIG. 5A, the capacitor structure 260 includes the first conductive layer 262, the insulator layer 264 over the first conductive layer 262, and the first work function metal layer 302 that is between the insulator layer 264 and the first conductive layer 262. As further shown in FIG. 5A, the capacitor structure 260 includes the second conductive layer 266 over the insulator layer 264, and the second work function metal layer 304 between the insulator layer 264 and the second conductive layer 266. The capacitor structure 260 includes additional features described in connection with FIG. 2, including the bottom metal contact 268, the top metal contact 270, and the capping layers 278 and 280.

In FIG. 5A, the first conductive layer 262, the first work function metal layer 302, the insulator layer 264, the second work function metal layer 304, and the second conductive layer 266 are approximately non-planar.

In some implementations, and as shown in FIG. 5B, the capacitor structure 260 of implementation 500 (e.g., a deep trench capacitor structure) is included in a wafer-on-wafer (WoW) product formed using a wafer-on-wafer (WoW) stack 502. As an example, the WoW stack 502 may include a semiconductor substrate 504 including logic circuitry that is joined with a semiconductor substrate 506 including additional circuitry and/or features (redistribution layers, portions of capacitor structures, and/or connection structures such as solder bumps, among other examples). The semiconductor substrate 504 and the semiconductor substrate 506 may be joined along a bond interface 508 using a eutectic bonding operation.

Circuitry and/or features included in and/or on the semiconductor substrate 504 may be formed independently from circuitry and/or features included in and/or on the semiconductor substrate 506. For example, using one or more operations described in connection with FIGS. 4A-4U, formation of the circuitry and/or features may include forming an upper portion 510 of the capacitor structure 260.

Additionally, or alternatively, circuitry and/or features included in and/or on the semiconductor substrate 506 may be formed independently from circuitry and/or features included in and/or on the semiconductor substrate 504. For example, using one or more operations described in connection with FIGS. 4A-4U, formation of the circuitry and/or features may include forming a lower portion 512 of the capacitor structure 260.

As shown in FIG. 5B, the capacitor structure 260 has a width D3 and a depth D4. In some implementations, the width D3 (a critical dimension) is included in a range of approximately 0.05 microns (μm) to approximately 0.5 μm. If the width D3 is less than approximately 0.05 μm, a trench used to form the capacitor structure 260 may be incompatible with manufacturing capabilities of semiconductor processing tools used to form the capacitor structure 260 (“bridging” or merging of conductive layers and or insulator layers of the capacitor structure 260 may occur during deposition by the deposition tool 102, among other examples). If the width D3 is greater than approximately 0.5 μm, the capacitor structure 260 may be oversized and increase an amount of resources consumed during fabrication of the WoW product including the capacitor structure 260. However, other values and ranges for the width D3 are within the scope of the present disclosure.

In some implementations, the depth D4 is included in a range of approximately 1.0 μm to approximately 15.0 μm. If the depth D4 is less than approximately 1.0 μm, the capacitor structure 260 may be undersized and not have a capacitance that satisfies a performance threshold. If the depth D4 is greater than approximately 15.0 μm, the trench used to form the capacitor structure 260 may be incompatible with manufacturing capabilities of semiconductor processing tools used to form the capacitor structure 260 (“bridging” or merging of conductive layers and or insulator layers of the capacitor may occur during deposition by the deposition tool 102, among other examples). However, other values and ranges for the depth D4 are within the scope of the present disclosure.

In accordance with the width D3 and the depth D4, an aspect ratio (e.g., a depth-to-width aspect ratio of the capacitor structure 260) may be included in a range of approximately 2:1 to approximately 400:1. However, other values and ranges for the aspect ratio of the capacitor structure 260 are within the scope of the present disclosure.

As indicated above, FIGS. 5A and 5B are provided as examples. Other examples may differ from what is described with regard to FIGS. 5A and 5B.

FIG. 6 is a diagram of an example implementation 600 of a capacitor structure 260 described herein. In contrast to implementation 300 of FIGS. 3A and 3B, the capacitor structure 260 of FIG. 6 may include multiple capacitor plate structures and correspond to a multi-level structure. Additionally, or alternatively, in implementation 600, the capacitor structure may correspond to a metal-insulator-metal (MIM) decoupling capacitor structure. One or more features of the capacitor structure 260 of the implementation 600 may be formed using one or more operations described in connection with FIGS. 4A-4U.

As shown in FIG. 6, the capacitor structure 260 is within the dielectric layer 222. The capacitor structure 260 includes the first conductive layer 262, the insulator layer 264 over the first conductive layer 262, the first work function metal layer 302 between the insulator layer 264 and the first conductive layer 262, the second conductive layer 266 over the insulator layer 264, and the second work function metal layer 304 between the insulator layer 264 and the second conductive layer 266.

The capacitor structure 260, as shown in FIG. 6, includes a third conductive layer 602, a third work function metal layer 604, and a fourth work function metal layer 606. The capacitor structure 260 of FIG. 6 further includes additional features described in connection with FIG. 2, including the bottom metal contact 268, the top metal contact 270, and the capping layers 278 and 280.

As shown in FIG. 6, the capacitor structure 260 includes three plate structures (e.g., plate structures 608, 610, and 612). Each plate structure may include one or more portions of an insulator layer (e.g., one or more portions of the insulator layer 264), one or more portions of a conductive layer (e.g., one or more portions of the first conductive layer 262, the second conductive layer 266, and/or the third conductive layer 602), and/or one or more portions of a work function metal layer (e.g., one or more portions the first work function metal layer 302, the second work function metal layer 304, the third work function metal layer 604, and/or the fourth work function metal layer 606).

As indicated above, FIG. 6 is provided as an example. Other examples may differ from what is described with regard to FIG. 6.

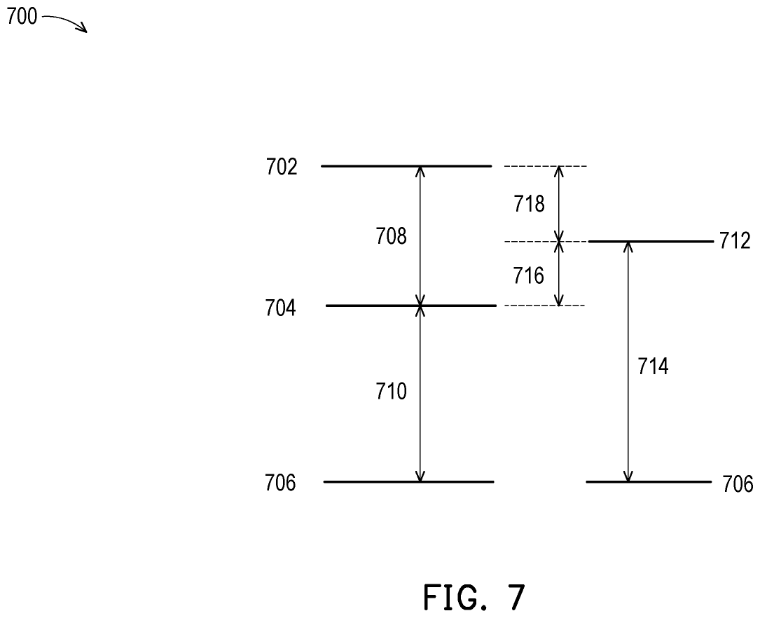

FIG. 7 is a diagram of example performance data 700 related to the capacitor structure 260 described herein. The performance data 700 shows details of one or more parameters related to energy levels (e.g., energy levels in electron volts (eV)) of a capacitor structure (e.g., the capacitor structure 260) including one or more work function metal layers (e.g., the work function metal layers 302 and/or 304).

FIG. 7 shows a conduction energy level (E_{c}) 702 relative to a valence band maximum energy level (VBM) 704 and a conduction band edge level (CL) 706. The E_{c} 702 represents an amount of energy needed to excite an electron (e.g., an electron stored in the capacitor structure 260) from a valence band to a conduction band (e.g., discharge the electron from the capacitor structure 260). The VBM 704 represents a maximum energy level for an electron to remain within the valance band, and the CL 706 represents a minimum energy level for an electron to remain within the conduction band.

As further shown in FIG. 7, an energy difference referred to as a band gap energy level (E_{g}) 708 separates the E_{c} 702 and the VBM 704. Furthermore, and as show in FIG. 7, an energy level difference referred to as a valence band offset (VBO) 710 separates the VBM 704 and the CL 706. FIG. 7 also shows a Fermi energy level (E_{f}) 712 that separates energy states (e.g., the valence band and the conduction band). A binding energy level (BE) 714, as shown in FIG. 7, reflects an amount of energy that may be needed to remove an electron from an atom or a molecule (e.g., an atom or a molecule within the capacitor structure 260).

By introducing a work function metal layer to the capacitor structure (e.g., the work function metal layers 302 and/or 304), the BE 714 may increase by an amount equivalent to the hole barrier height 716 of a material included in the work function metal layer to change and/or increase an electron barrier height 718. By increasing the electron barrier height 718 (and/or the BE 714), an amount of capacitance in the capacitor structure may be increased. Additionally, or alternatively, an amount of leakage from the capacitor structure may be reduced.

As indicated above, FIG. 7 is provided as an example. Other examples may differ from what is described with regard to FIG. 7.

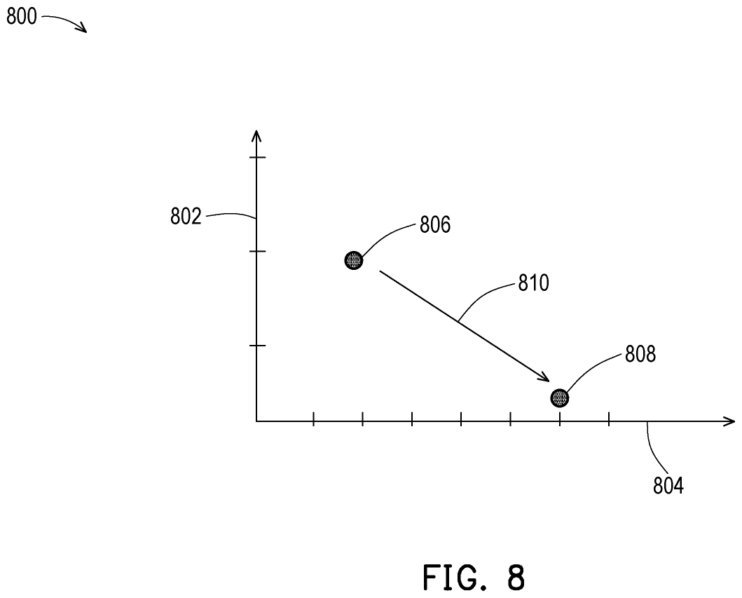

FIG. 8 is a diagram of example performance data 800 related to the capacitor structure 260 described herein. The performance data 800 illustrates leakage characteristics of the capacitor structure 260, where an amount of leakage 802 (e.g., an amount of leakage in nanoamps) is charted against an electron barrier height 804 (e.g., an electron barrier height 804 in eV).

Data point 806 illustrates the amount of leakage 802 for a capacitor structure not including work function metal layers (e.g., the first work function metal layer 302 and the second work function metal layer 304, among other examples). Data point 808 illustrates the amount of leakage 802 for the capacitor structure 260 including the work function metal layers as described in connection with FIGS. 3A-6 and elsewhere herein (the first work function metal layer 302 and the second work function metal layer 304, among other examples).

As shown in FIG. 8, the electron barrier height 804 associated with the data point 808 is greater relative to the electron barrier height 804 associated with the data point 806. Further, as shown in FIG. 8, the data point 808 realizes an improvement 810 (e.g., a reduction in the amount of leakage 802) relative to data point 806 based on an increase in the electron barrier height 804.

As an example, and in some implementations, the improvement 810 (e.g., the reduction in the amount of leakage 802) may be included in a range of approximately 80% to approximately 97%. However, other values and ranges for the improvement 810 are within the scope of the present disclosure.

As indicated above, FIG. 8 is provided as an example. Other examples may differ from what is described with regard to FIG. 8.

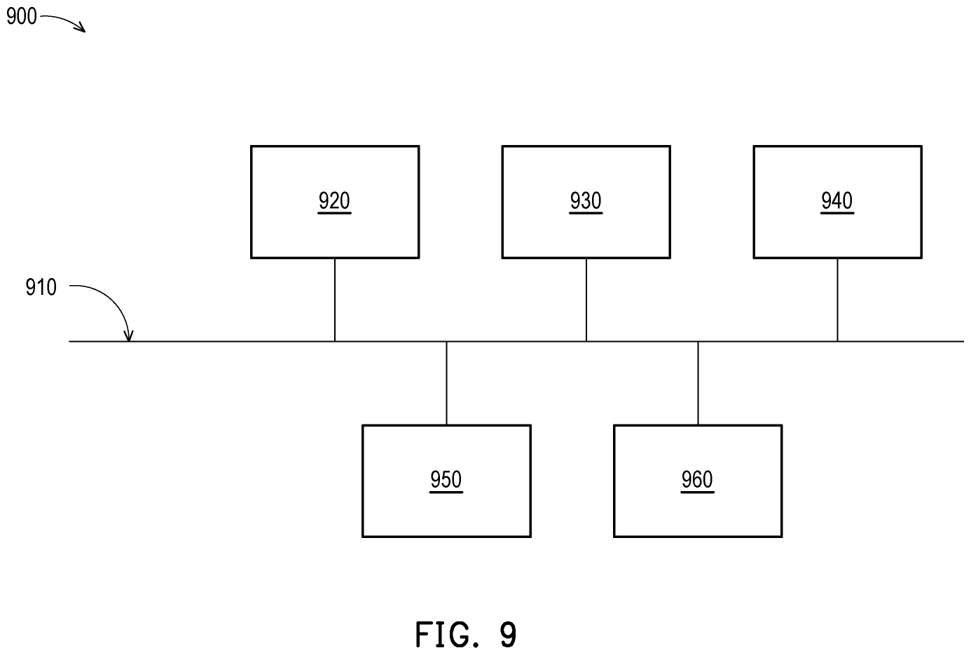

FIG. 9 is a diagram of example components of a device 900 described herein. In some implementations, one or more of the semiconductor processing tools 102-1142 and/or the wafer/die transport tool 114 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

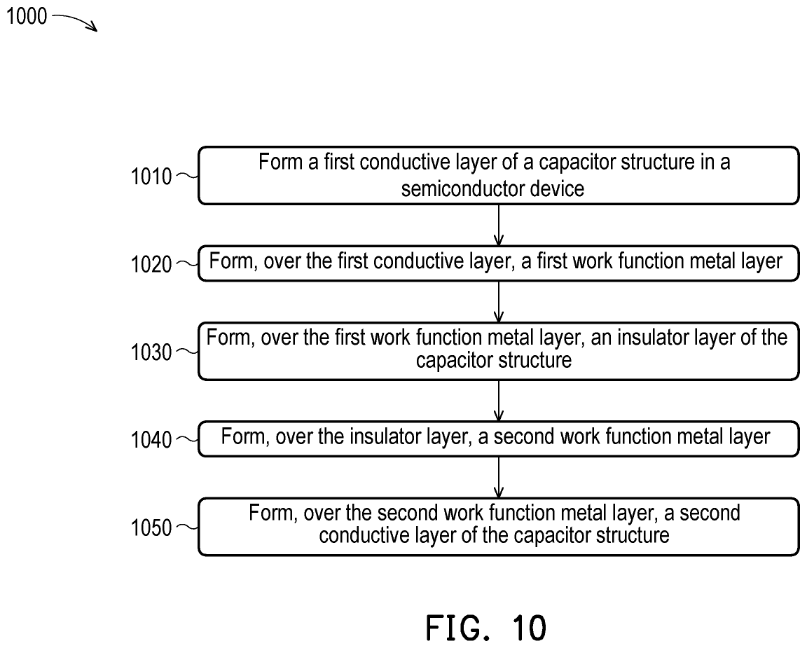

FIG. 10 is a flowchart of an example process 1000 associated with forming a capacitor structure including work function metal layers. In some implementations, one or more process blocks of FIG. 10 are performed by one or more semiconductor processing tools (e.g., one or more of the semiconductor processing tools 102-112). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming a first conductive layer of a capacitor structure in a semiconductor device (block 1010). For example, one or more of the semiconductor processing tools 102-112 may form a first conductive layer (e.g., the first conductive layer 262) of a capacitor structure (e.g., the capacitor structure 260) in a semiconductor device (e.g., the semiconductor device 200), as described herein.

As further shown in FIG. 10, process 1000 may include forming, over the first conductive layer, a first work function metal layer (block 1020). For example, one or more of the semiconductor processing tools 102-112 may form, over the first conductive layer, a first work function metal layer (e.g., the first work function metal layer 302), as described herein.

As further shown in FIG. 10, process 1000 may include forming, over the first work function metal layer, an insulator layer of the capacitor structure (block 1030). For example, one or more of the semiconductor processing tools 102-112 may form, over the first work function metal layer, an insulator layer (e.g., the insulator layer 264) of the capacitor structure, as described herein.

As further shown in FIG. 10, process 1000 may include forming, over the insulator layer, a second work function metal layer (block 1040). For example, one or more of the semiconductor processing tools 102-112 may form, over the insulator layer, a second work function metal layer (e.g., the second work function metal layer 304), as described herein.

As further shown in FIG. 10, process 1000 may include forming, over the second work function metal layer, a second conductive layer of the capacitor structure (block 1050). For example, one or more of the semiconductor processing tools 102-112 may form, over the second work function metal layer, a second conductive layer (e.g., the second conductive layer 266) of the capacitor structure, as described herein.

Process 1000 may include additional implementations, such as any single implementation or any combination of implementations described below and/or in connection with one or more other processes described elsewhere herein.

In a first implementation, forming the insulator layer includes depositing a hafnium oxide (HfO₂) material.

In a second implementation, alone or in combination with the first implementation, forming the first work function metal layer or the second work function metal layer includes forming the first work function metal layer or the second work function metal layer using an atomic layer deposition process.

In a third implementation, alone or in combination with one or more of the first and second implementations, forming the first work function metal layer or the second work function metal layer using an atomic layer deposition process includes performing a plasma treatment operation.

In a fourth implementation, alone or in combination with one or more of the first through third implementations, performing the plasma treatment operation includes using a nitrous oxide based plasma, a nitrogen based plasma, or an ozone based plasma.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In some implementations described herein, a capacitor structure may include a MIM structure in which work function metal layers are included between the insulator layer of the capacitor structure and the conductive electrode layers of the capacitor structure. The work function metal layers may enable high-k dielectric materials to be used for the insulator layer in that the work function metal layers may provide an increased electron barrier height between the insulator layer and the conductive electrode layers, which may increase the breakdown voltage and may reduce the current leakage for the capacitor structure.

In this way, the work function metal layers may increase the electron barrier height between the insulator layer and the conductive electrode layers, thereby enabling the capacitive capacity of the capacitor structure to be increased through the inclusion of high-k dielectric materials while minimizing the current leakage and/or breakdown voltage impact from the high-k dielectric materials.

As described in greater detail above, some implementations described herein provide a semiconductor device. The semiconductor device includes a dielectric layer. The semiconductor device includes a capacitor structure within the dielectric layer, where the capacitor structure includes a first conductive layer, an insulator layer over the first conductive layer, a second conductive layer over the insulator layer, and a work function metal layer between the insulator layer and at least one of the first conductive layer or the second conductive layer.

As described in greater detail above, some implementations described herein provide a method. The method includes forming a first conductive layer of a capacitor structure in a semiconductor device. The method includes forming, over the first conductive layer, a first work function metal layer. The method includes forming, over the first work function metal layer, an insulator layer of the capacitor structure. The method includes forming, over the insulator layer, a second work function metal layer. The method includes forming, over the second work function metal layer, a second conductive layer of the capacitor structure.

As described in greater detail above, some implementations described herein provide a semiconductor device. The semiconductor device includes a dielectric layer. The semiconductor device includes a capacitor structure within the dielectric layer, where the capacitor structure includes a first conductive layer, an insulator layer over the first conductive layer, a first work function metal layer between the insulator layer and the first conductive layer, a second conductive layer over the insulator layer, and a second work function metal layer between the insulator layer and the second conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a dielectric layer; and
a capacitor structure included in the dielectric layer,
wherein the capacitor structure comprises:
a first conductive layer;
an insulator layer over the first conductive layer;
a second conductive layer over the insulator layer; and
a work function metal layer between the insulator layer and at least one of the first conductive layer or the second conductive layer.

2. The semiconductor device of claim 1, wherein the capacitor structure corresponds to a planar capacitor structure.

3. The semiconductor device of claim 2, wherein the planar capacitor structure corresponds to a decoupling capacitor structure having three plate structures.

4. The semiconductor device of claim 1, wherein the capacitor structure corresponds to a deep trench capacitor structure.

5. The semiconductor device of claim 1, wherein the work function metal layer comprises:
a gold material,
a silver material,
a palladium material,
a platinum material,
an iridium material,
a ruthenium material,
a ruthenium oxide material,
a cobalt material,
a nickel material,
a copper material,
a tungsten carbon nitride material,
a tungsten nitride material, or
a molybdenum nitride material.

6. The semiconductor device of claim 1, wherein a thickness of the work function metal layer is lesser relative to a thickness of the at least one of the first conductive layer or the second conductive layer.

7. The semiconductor device of claim 1, wherein a thickness of the work function metal layer is included in a range of approximately 5 angstroms to approximately 250 angstroms.

8. The semiconductor device of claim 1, wherein the first conductive layer comprises:
a titanium nitride (TiN) material,
a tantalum nitride (TaN) material,
a molybdenum (Mo) material, or
a tungsten (W) material.

9. The semiconductor device of claim 1, wherein an oxygen concentration in the work function metal layer changes between a top surface of the work function metal layer and a bottom surface of the work function metal layer.

10. A method, comprising:
forming a first conductive layer of a capacitor structure in a semiconductor device;
forming, over the first conductive layer, a first work function metal layer;
forming, over the first work function metal layer, an insulator layer of the capacitor structure;
forming, over the insulator layer, a second work function metal layer; and
forming, over the second work function metal layer, a second conductive layer of the capacitor structure.

11. The method of claim 10, wherein forming the insulator layer comprises:
depositing a hafnium oxide (HfO₂) material.

12. The method of claim 10, wherein forming the first work function metal layer or the second work function metal layer comprises:
forming the first work function metal layer or the second work function metal layer using an atomic layer deposition process.

13. The method of claim 12, wherein forming the first work function metal layer or the second work function metal layer using an atomic layer deposition process comprises:
performing a plasma treatment operation.

14. The method of claim 13, wherein performing the plasma treatment operation comprises:
using a nitrous oxide based plasma, a nitrogen based plasma, or an ozone based plasma.

15. A semiconductor device, comprising:
a dielectric layer; and
a capacitor structure included in the dielectric layer,
wherein the capacitor structure comprises:
a first conductive layer;
an insulator layer over the first conductive layer;
a first work function metal layer between the insulator layer and the first conductive layer;
a second conductive layer over the insulator layer; and
a second work function metal layer between the insulator layer and the second conductive layer.

16. The semiconductor device of claim 15, wherein the first work function metal layer and the second work function metal layer each comprises:
a material having a bandgap energy level that is included in a range of approximately 4.5 electron volts to approximately 6.0 electron volts.

17. The semiconductor device of claim 15, wherein the first work function metal layer and the second work function metal layer each comprises:
a material having a Gibbs free energy that is included in a range of approximately −135 kilojoules per mol to approximately −970 kilojoules per mol.

18. The semiconductor device of claim 15, wherein a nitrogen concentration in the first work function metal layer changes between a top surface of the first work function metal layer and a bottom surface of the first work function metal layer.

19. The semiconductor device of claim 15, wherein the capacitor structure comprises a planar capacitor structure in which the first conductive layer, the first work function metal layer, the insulator layer, the second work function metal layer, and the second conductive layer are approximately planar.

20. The semiconductor device of claim 15, wherein the capacitor structure comprises a non-planar capacitor structure in which the first conductive layer, the first work function metal layer, the insulator layer, the second work function metal layer, and the second conductive layer are non-planar.
